(19) United States
(12) Patent Application Publication
(10) Pub. No.: US 2024/0333223 A1
(43) Pub. Date: Oct. 3, 2024

(54) TRACKER MODULE

(71) Applicant: Murata Manufacturing Co., Ltd., Nagaokakyo-shi (JP)

(72) Inventors: Kenzou OOMORI, Nagaokakyo-shi (JP); Mikiko FUKASAWA, Nagaokakyo-shi (JP); Takayuki TOMITA, Nagaokakyo-shi (JP); Takeshi KOGURE, Nagaokakyo-shi (JP); Toshiki MATSUI, Nagaokakyo-shi (JP); Yuuki FUKUDA, Nagaokakyo-shi (JP)

(21) Appl. No.: 18/738,521

(22) Filed: Jun. 10, 2024

Related U.S. Application Data
(63) Continuation of application No. PCT/JP2022/048533, filed on Dec. 28, 2022.

(30) Foreign Application Priority Data
Jan. 11, 2022 (JP) 2022-002121

(51) Int. Cl. H03F 1/02; H03F 3/24

(52) U.S. Cl. CPC H03F 1/0233; H03F 3/245; H03F 2200/105; H03F 2200/451

(57) ABSTRACT

A tracker module includes a module laminate, and an integrated circuit disposed on the module laminate, in which the integrated circuit includes one or more first switches included in a pre-regulator circuit, one or more second switches included in a switched-capacitor circuit, one or more third switches included in a supply modulator, a power supply terminal connected to at least one of the one or more first switches, the one or more second switches, and the one or more second switches, and a control terminal that receives a DCL signal, and in a plan view of the module laminate, the power supply terminal has a larger size than the control terminal.

### CROSS REFERENCE TO RELATED APPLICATIONS

This application is a continuation of International Application No. PCT/JP2022/048533, filed Dec. 28, 2022, which claims priority to Japanese Patent Application No. 2022-002121, filed Jan. 11, 2022, the entire contents of each of which are hereby incorporated by reference in their entirety.

### TECHNICAL FIELD

The present disclosure relates to a tracker module.

### BACKGROUND

An example circuit, as described in U.S. Pat. No. 9,755,672, includes a power supply modulation circuit that can supply a power supply voltage dynamically adjusted over time in accordance with a radio frequency signal to a power amplifier.

In a case that the power supply modulation circuit (power supply circuit) is mounted on a module laminate, characteristics may deteriorate because of heat.

### SUMMARY OF THE INVENTION

Therefore, the present disclosure provides a tracker module that suppresses characteristic deterioration caused by heat.

In an exemplary aspect, a tracker module of the present disclosure is provided that includes a module laminate, and at least one integrated circuit disposed on the module laminate, in which the at least one integrated circuit includes at least one switch (also referred to as one or more first switches) included in a pre-regulator circuit that is configured to convert an input voltage into a first voltage, at least one switch (also referred to as one or more second switches) included in a switched-capacitor circuit that is configured to generate a plurality of second voltages having a plurality of respective discrete voltage levels from the first voltage, at least one switch (also referred to as one or more third switches) included in a supply modulator that is configured to select at least one of the plurality of second voltages based on a digital control logic signal that is generated based on an envelope signal, a power supply terminal connected to at least one of the at least one switch included in the pre-regulator circuit, the at least one switch included in the switched-capacitor circuit, and the at least one switch included in the supply modulator, and a control terminal that receives the digital control logic signal, and in a plan view of the module laminate, the power supply terminal has a larger size than the control terminal.

In another exemplary aspect, a tracker module of the present disclosure includes a module laminate, and at least one integrated circuit disposed on the module laminate, in which the at least one integrated circuit includes at least one switch included in a pre-regulator circuit, at least one switch included in a switched-capacitor circuit, at least one switch included in a supply modulator, a power supply terminal connected to at least one of the at least one switch included in the pre-regulator circuit, the at least one switch included in the switched-capacitor circuit, and the at least one switch included in the supply modulator, and a control terminal that receives a digital control logic signal, in a plan view of the module laminate, the power supply terminal is larger than the control terminal, the switched-capacitor circuit includes a first capacitor including a first electrode and a second electrode, and a second capacitor including a third electrode and a fourth electrode, the at least one switch included in the switched-capacitor circuit includes a first switch, a second switch, a third switch, a fourth switch, a fifth switch, a sixth switch, a seventh switch, and an eighth switch, one end of the first switch and one end of the third switch are connected to the first electrode, one end of the second switch and one end of the fourth switch are connected to the second electrode, one end of the fifth switch and one end of the seventh switch are connected to the third electrode, one end of the sixth switch and one end of the eighth switch are connected to the fourth electrode, the other end of the first switch, the other end of the second switch, the other end of the fifth switch, and the other end of the sixth switch are connected to each other, the other end of the third switch is connected to the other end of the seventh switch, the other end of the fourth switch is connected to the other end of the eighth switch, the supply modulator includes an output terminal, the at least one switch included in the supply modulator includes a ninth switch connected between the output terminal and the other end of the first switch, the other end of the second switch, the other end of the fifth switch, and the other end of the sixth switch, and a tenth switch connected between the output terminal and the other end of the third switch and the other end of the seventh switch, the pre-regulator circuit includes an input terminal, the at least one switch included in the pre-regulator circuit includes an eleventh switch connected between the input terminal and one end of a power inductor, and a twelfth switch connected between the one end of the power inductor and a ground, and the other end of the power inductor is connected to the other end of the first switch, the other end of the second switch, the other end of the fifth switch, and the other end of the sixth switch.

In another exemplary aspect, a tracker module of the present disclosure includes a module laminate, and at least one integrated circuit disposed on the module laminate, in which the at least one integrated circuit includes at least one switch included in a pre-regulator circuit that is configured to convert an input voltage into a first voltage, at least one switch included in a switched-capacitor circuit that is configured to generate a plurality of second voltages having a plurality of respective discrete voltage levels from the first voltage, at least one switch included in a supply modulator that is configured to select at least one of the plurality of second voltages based on an envelope signal, and a power supply terminal connected to at least one of the at least one switch included in the pre-regulator circuit, the at least one switch included in the switched-capacitor circuit, and the at least one switch included in the supply modulator, and in a plan view of the module laminate, the power supply terminal has an elongated shape.

According to the tracker module according to an exemplary aspect of the present disclosure, characteristic deterioration caused by heat are suppressed.

### BRIEF DESCRIPTION OF DRAWINGS

FIG. 1 is a circuit configuration diagram of a communication device according to an exemplary embodiment.

FIG. 2A is a circuit configuration diagram of a pre-regulator circuit, a switched-capacitor circuit, supply modulators, and filter circuits according to the exemplary embodiment.

FIG. 2B is a circuit configuration diagram of a digital control circuit according to the exemplary embodiment.

FIG. 3A is a graph illustrating a power supply voltage supplied in a digital envelope tracking mode.

FIG. 3B is a graph illustrating a power supply voltage supplied in an analog envelope tracking mode.

FIG. 4 is a plan view of a tracker module according to an example.

FIG. 5 is a plan view of the tracker module according to the example.

FIG. 6 is a cross-sectional view of the tracker module according to the example.

FIG. 7 is a cross-sectional view of the tracker module according to the example.

FIG. 8 is a disposition diagram of terminals of an integrated circuit according to the example.

FIG. 9A is a plan view of a power supply terminal of an integrated circuit according to a modification example.

FIG. 9B is a plan view of a power supply terminal of an integrated circuit according to a modification example.

FIG. 9C is a plan view of a power supply terminal of an integrated circuit according to a modification example.

### DETAILED DESCRIPTION OF EMBODIMENTS

Hereinafter, an exemplary embodiment of the present disclosure will be described in detail using the drawings. Any embodiment described below illustrates a comprehensive or specific example. Numerical values, shapes, materials, constituents, a disposition and a connection form of the constituents, and the like illustrated in the following exemplary embodiment are examples and are not intended to limit the present disclosure.

Each drawing is a schematic diagram that is highlighted, omitted, or adjusted in ratio, as appropriate, to illustrate the present disclosure and is not necessarily illustrated in a strict sense. Each drawing may have different shapes, positional relationships, and ratios from those in actuality. Substantially the same configurations are designated by the same reference signs in each drawing, and duplicate descriptions may be omitted or simplified.

In each drawing below, an x-axis and a y-axis are axes that are orthogonal to each other on a plane parallel to a main surface of a module laminate. According to an exemplary aspect, in a case where the module laminate has a rectangular shape in a plan view, the x-axis is parallel to a first edge of the module laminate, and the y-axis is parallel to a second edge of the module laminate that is orthogonal to the first edge. In addition, a z-axis is an axis perpendicular to the main surface of the module laminate. A positive direction of the z-axis indicates an upward direction, and a negative direction of the z-axis indicates a downward direction.

In a circuit configuration of the present disclosure, the term “connected” includes not only a case of being directly connected through a connection terminal and/or a wire conductor but also a case of being electrically connected through other circuit elements. The expression “connected between A and B” means being connected to both A and B between A and B and means being connected in series to a path connecting A to B.

In component disposition of the present disclosure, the expression “a component is disposed on a laminate” includes a case where the component is disposed on a main surface of the laminate, and a case where the component is disposed in the laminate. The expression “the component is disposed on the main surface of the laminate” includes, in addition to a case where the component is disposed in contact with the main surface of the laminate, a case where the component is disposed above the main surface without being in contact with the main surface (for example, the component is laminated on another component disposed in contact with the main surface). In addition, the expression “the component is disposed on the main surface of the laminate” may include a case where the component is disposed in a recessed portion formed in the main surface. The expression “the component is disposed in the laminate” includes, in addition to a case where the component is encapsulated in the module laminate, a case where the entire component is disposed between both main surfaces of the laminate and a part of the component is not covered with the laminate, and a case where only a part of the component is disposed in the laminate.

In addition, in the component disposition of the present disclosure, the expression “a plan view of the module laminate” means viewing an object orthogonally projected to an xy plane from a positive side of the z-axis. The expression “A overlaps B in the plan view” means that a region of A orthogonally projected to the xy plane overlaps a region of B orthogonally projected to the xy plane. In addition, the expression “A is larger than B in the plan view of the module laminate” means that an area of the region of A orthogonally projected to the xy plane is larger than an area of the region of B orthogonally projected to the xy plane. The area of the region of each of A and B orthogonally projected to the xy plane can be specified by recognizing the region of each of A and B in an image of a module captured by irradiating the module with an X-ray from a z direction. A frequency and an intensity of the X-ray may be determined in accordance with materials of A and B and other members in the module.

In addition, in the component disposition of the present disclosure, the expression “C is closer to A than B” means that a distance between A and C is shorter than a distance between A and B. Here, the expression “the distance between A and B” means the shortest distance between A and B. That is, the expression “the distance between A and B” means a length of the shortest line segment among a plurality of line segments connecting any point on the surface of A to any point on a surface of B.

In addition, terms such as “parallel” and “perpendicular” indicating a relationship between elements, terms such as “rectangular” indicating a shape of an element, and numerical value ranges do not only represent a strict meaning but also mean that a substantially equivalent range including, for example, an error of approximately a few % is included.

### Exemplary Embodiment

Hereinafter, a tracker module and a communication device according to the present exemplary embodiment will be described with reference to the drawings.

### [1 Circuit Configuration]

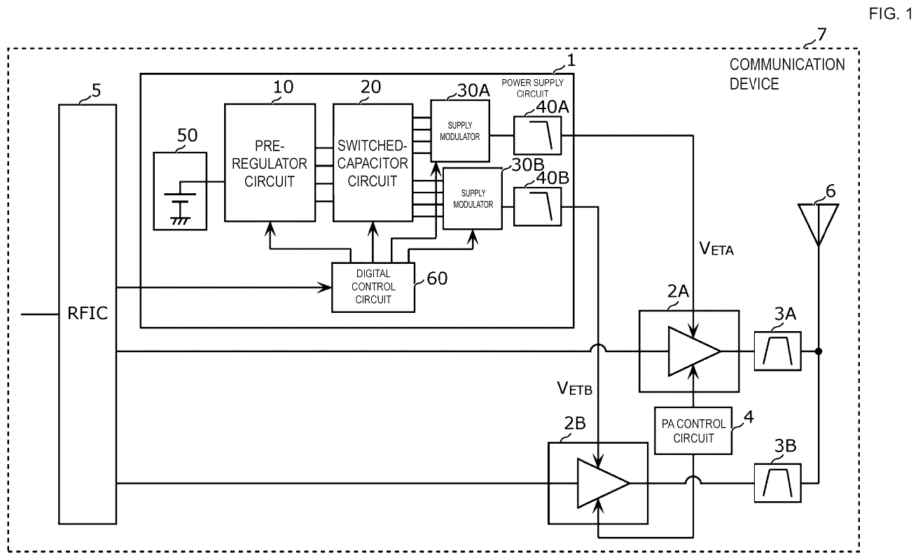

A circuit configuration of a communication device 7 according to the present exemplary embodiment will be described with reference to FIG. 1. FIG. 1 is a circuit configuration diagram of the communication device 7 according to the present exemplary embodiment.

### [1.1 Circuit Configuration of Communication Device 7]

First, the circuit configuration of the communication device 7 will be described. As illustrated in FIG. 1, the communication device 7 according to the present exemplary embodiment includes a power supply circuit 1, power amplifiers 2A and 2B, filters 3A and 3B, a power amplifier (PA) control circuit 4, a radio frequency integrated circuit (RFIC) 5, and an antenna 6.

The power supply circuit 1 can supply power supply voltages V_{ETA} and V_{ETB} to the power amplifiers 2A and 2B, respectively, in a digital envelope tracking (ET) mode. In the digital ET mode, a voltage level of each of the power supply voltages V_{ETA} and V_{ETB} IS selected from a plurality of discrete voltage levels based on a digital control signal corresponding to an envelope signal and changes over time.

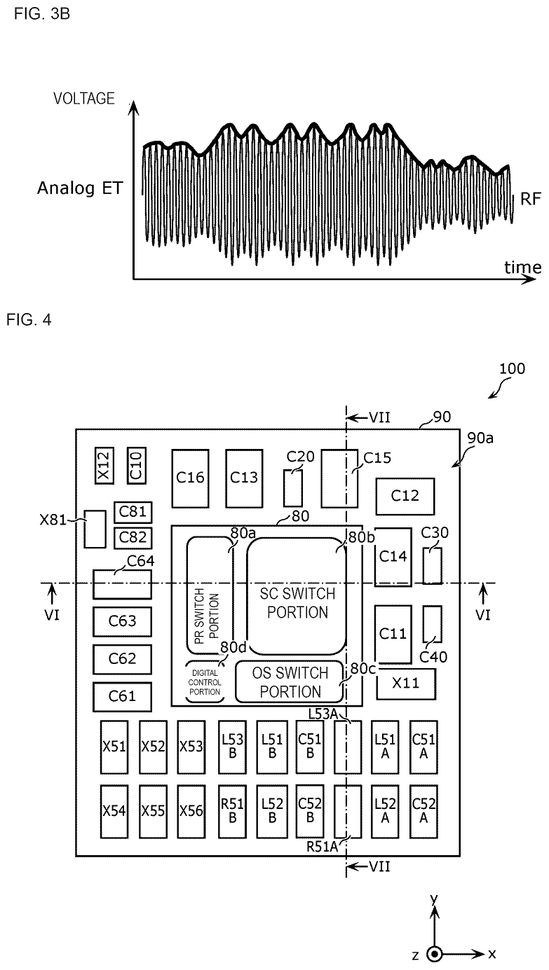

The envelope signal is a signal indicating an envelope value of a modulated signal (radio frequency signal). The envelope value is represented by, for example, a square root of (I²+Q²). Here, (I, Q) represents a constellation point. The constellation point is a point representing a signal modulated by digital modulation on a constellation diagram. Details of the digital ET mode will be described later using FIGS. 3A and 3B.

While the power supply circuit 1 supplies the two power supply voltages V_{ETA} and V_{ETB} to the two power amplifiers 2A and 2B, respectively, in FIG. 1, the power supply circuit 1 may supply the same power supply voltage to a plurality of power amplifiers. In addition, the power supply circuit 1 may supply a power supply voltage to only one power amplifier.

As illustrated in FIG. 1, the power supply circuit 1 includes a pre-regulator circuit 10, a switched-capacitor circuit 20, supply modulators 30A and 30B, filter circuits 40A and 40B, a direct current power source 50, and a digital control circuit 60.

The pre-regulator circuit 10 includes a power inductor and switches. The power inductor is an inductor configured for stepping up and/or stepping down a direct current voltage. The power inductor is disposed in series on a direct current path. The power inductor may be connected (disposed in parallel) between the direct current path and the ground. The pre-regulator circuit 10 can convert an input voltage into a first voltage using the power inductor. The pre-regulator circuit 10 may be referred to as a magnetic regulator or a direct current (DC)-to-DC converter.

The switched-capacitor circuit 20 includes a plurality of capacitors and a plurality of switches. The switched-capacitor circuit 20 can generate a plurality of second voltages having the plurality of respective discrete voltage levels from the first voltage from the pre-regulator circuit 10. The switched-capacitor circuit 20 may be referred to as a switched-capacitor voltage balancer.

The supply modulators 30A and 30B can select one of the plurality of second voltages generated by the switched-capacitor circuit 20 and output the selected voltage to the filter circuits 40A and 40B, respectively, based on the digital control signal corresponding to the envelope signal.

The filter circuits 40A and 40B can filter signals (second voltages) from the supply modulators 30A and 30B.

The direct current power source 50 can supply a direct current voltage to the pre-regulator circuit 10. For example, a rechargeable battery can be configured as the direct current power source 50. However, the present disclosure is not limited thereto.

The digital control circuit 60 can control the pre-regulator circuit 10, the switched-capacitor circuit 20, and the supply modulators 30A and 30B based on the digital control signal from the RFIC 5.

It is possible that the power supply circuit 1 does not include at least one of the pre-regulator circuit 10, the switched-capacitor circuit 20, the supply modulators 30A and 30B, the filter circuits 40A and 40B, the direct current power source 50, and the digital control circuit 60. For example, in a case where the power supply voltage is supplied to only one power amplifier 2A, it is possible that the power supply circuit 1 does not include the supply modulator 30B or the filter circuit 40B. In addition, it is possible that the power supply circuit 1 does not include the direct current power source 50 or the power supply circuit 1 does not include the filter circuit 40A or 40B. In addition, any combination of the pre-regulator circuit 10, the switched-capacitor circuit 20, the supply modulators 30A and 30B, and the filter circuits 40A and 40B may be integrated into a single circuit.

The power amplifier 2A is connected between the RFIC 5 and the filter 3A. Furthermore, the power amplifier 2A can receive the power supply voltage V_{ETA} from the power supply circuit 1 and can receive a bias signal from the PA control circuit 4. Accordingly, the power amplifier 2A can amplify a transmission signal of a band A received from the RFIC 5.

The power amplifier 2B is connected between the RFIC 5 and the filter 3B. Furthermore, the power amplifier 2B can receive the power supply voltage V_{ETB} from the power supply circuit 1 and can receive the bias signal from the PA control circuit 4. Accordingly, the power amplifier 2B can amplify a transmission signal of a band B received from the RFIC 5.

The filter 3A is connected between the power amplifier 2A and the antenna 6. The filter 3A has a passband including the band A. Accordingly, the transmission signal of the band A amplified by the power amplifier 2A can pass through the filter 3A.

The filter 3B is connected between the power amplifier 2B and the antenna 6. The filter 3B has a passband including the band B. Accordingly, the transmission signal of the band B amplified by the power amplifier 2B can pass through the filter 3B.

The PA control circuit 4 can control the power amplifiers 2A and 2B. According to an exemplary aspect, the PA control circuit 4 can supply the bias signal to each of the power amplifiers 2A and 2B.

The RFIC 5 is an example of a signal processing circuit that processes a radio frequency signal. According to an exemplary aspect, the RFIC 5 performs signal processing such as upconversion on an input transmission signal and supplies the radio frequency transmission signal generated through the signal processing to the power amplifiers 2A and 2B. In addition, the RFIC 5 includes a control circuit that controls the power supply circuit 1. A part or all of functions of the RFIC 5 as the control circuit may be mounted outside the RFIC 5.

The antenna 6 transmits the signal of the band A input from the power amplifier 2A through the filter 3A and the signal of the band B input from the power amplifier 2B through the filter 3B.

The bands A and B are frequency bands for a communication system constructed using a Radio Access Technology (RAT). The bands A and B are defined in advance by a standardizing body and the like (for example, 3rd Generation Partnership Project (3GPP)® and Institute of Electrical and Electronics Engineers (IEEE)). Examples of the communication system include a 5th Generation New Radio (5G NR) system, a Long Term Evolution (LTE) system, and a wireless local area network (WLAN) system.

The circuit configuration of the communication device 7 illustrated in FIG. 1 is an example, and the present disclosure is not limited thereto. For example, it is possible that the communication device 7 does not include the antenna 6. In addition, for example, the communication device 7 may include a plurality of antennas.

### [1.2 Circuit Configuration of Power Supply Circuit 1]

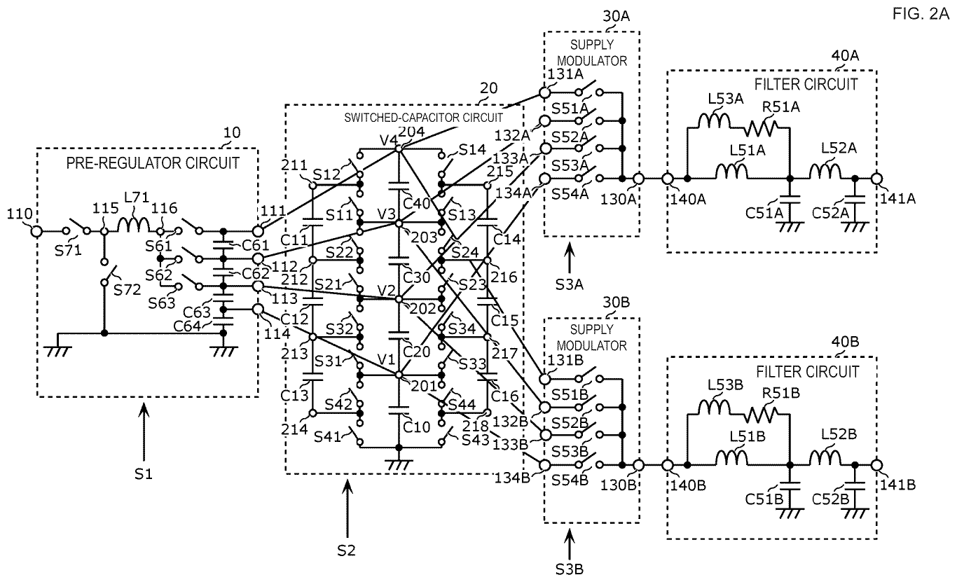

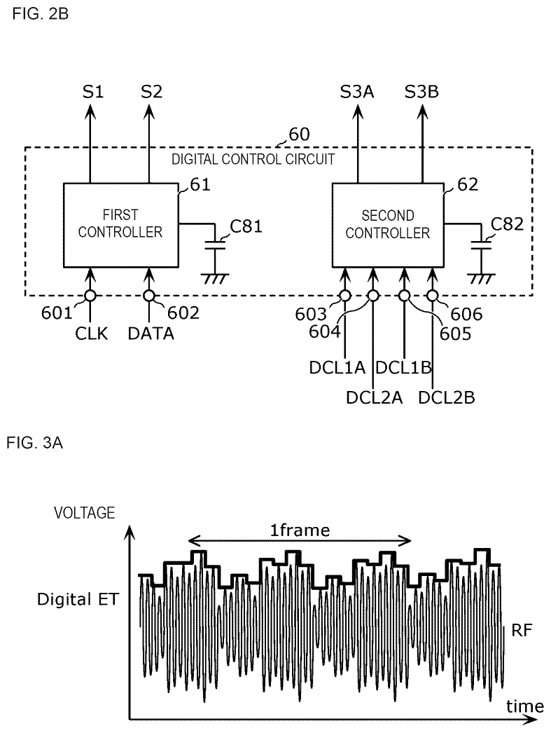

Next, circuit configurations of the pre-regulator circuit 10, the switched-capacitor circuit 20, the supply modulators 30A and 30B, the filter circuits 40A and 40B, and the digital control circuit 60 included in the power supply circuit 1 will be described with reference to FIGS. 2A and 2B. FIG. 2A is a circuit configuration diagram of the pre-regulator circuit 10, the switched-capacitor circuit 20, the supply modulators 30A and 30B, and the filter circuits 40A and 40B according to the present exemplary embodiment. FIG. 2B is a circuit configuration diagram of the digital control circuit 60 according to the present exemplary embodiment.

FIGS. 2A and 2B are exemplary circuit configurations, and the pre-regulator circuit 10, the switched-capacitor circuit 20, the supply modulators 30A and 30B, the filter circuits 40A and 40B, and the digital control circuit 60 may be mounted using any of various circuit mounting and circuit techniques. Accordingly, description of each circuit provided below is not to be interpreted as being limiting.

### [1.2.1 Circuit Configuration of Switched-Capacitor Circuit 20]

First, the circuit configuration of the switched-capacitor circuit 20 will be described. As illustrated in FIG. 2A, the switched-capacitor circuit 20 includes capacitors C11 to C16, capacitors C10, C20, C30, and C40, switches S11 to S14, S21 to S24, S31 to S34, and S41 to S44, and terminals 201 to 204 and 211 to 218. Energy and charges are input into the switched-capacitor circuit 20 from the pre-regulator circuit 10 through the terminals 201 to 204 and are drawn to the supply modulators 30A and 30B from the switched-capacitor circuit 20 through the terminals 201 to 204.

Each of the terminals 201 to 204 is an example of a fifth power supply terminal and a sixth power supply terminal and is connected to at least one of the switches included in the switched-capacitor circuit 20. Furthermore, each of the terminals 201 to 204 is connected to at least one of the switches included in the pre-regulator circuit 10 and is connected to at least one of the switches included in the supply modulators 30A and 30B.

Each of the terminals 211 to 218 is an example of a second power supply terminal and is connected to the switches and flying capacitors included in the switched-capacitor circuit 20.

Each of the capacitors C11 to C16 functions as a flying capacitor (may be referred to as a transfer capacitor). That is, each of the capacitors C11 to C16 is configured for stepping up or stepping down the first voltage supplied from the pre-regulator circuit 10. More specifically, the capacitors C11 to C16 cause charges to move between the capacitors C11 to C16 and the terminals 201 to 204 such that voltages V1 to V4 (voltages with respect to a ground potential) satisfying V1:V2:V3:V4=1:2:3:4 are maintained in the four terminals 201 to 204. The voltages V1 to V4 correspond to the plurality of second voltages having the plurality of respective discrete voltage levels.

The capacitor C11 includes two electrodes. One of the two electrodes of the capacitor C11 is connected to one end of the switch S11 and one end of the switch S12 through the terminal 211. The other of the two electrodes of the capacitor C11 is connected to one end of the switch S21 and one end of the switch S22 through the terminal 212.

The capacitor C12 is an example of a first capacitor and includes two electrodes (examples of a first electrode and a second electrode). One of the two electrodes of the capacitor C12 is connected to one end of the switch S21 and one end of the switch S22 through the terminal 212. The other of the two electrodes of the capacitor C12 is connected to one end of the switch S31 and one end of the switch S32 through the terminal 213.

The capacitor C13 includes two electrodes. One of the two electrodes of the capacitor C13 is connected to one end of the switch S31 and one end of the switch S32 through the terminal 213. The other of the two electrodes of the capacitor C13 is connected to one end of the switch S41 and one end of the switch S42 through the terminal 214.

The capacitor C14 includes two electrodes. One of the two electrodes of the capacitor C14 is connected to one end of the switch S13 and one end of the switch S14 through the terminal 215. The other of the two electrodes of the capacitor C14 is connected to one end of the switch S23 and one end of the switch S24 through the terminal 216.

The capacitor C15 is an example of a second capacitor and includes two electrodes (examples of a third electrode and a fourth electrode). One of the two electrodes of the capacitor C15 is connected to one end of the switch S23 and one end of the switch S24 through the terminal 216. The other of the two electrodes of the capacitor C15 is connected to one end of the switch S33 and one end of the switch S34 through the terminal 217.

The capacitor C16 includes two electrodes. One of the two electrodes of the capacitor C16 is connected to one end of the switch S33 and one end of the switch S34 through the terminal 217. The other of the two electrodes of the capacitor C16 is connected to one end of the switch S43 and one end of the switch S44 through the terminal 218.

Each of a set of the capacitors C11 and C14, a set of the capacitors C12 and C15, and a set of the capacitors C13 and C16 can be charged and discharged in a complementary manner by repeating a first phase and a second phase.

According to an exemplary aspect, in the first phase, the switches S12, S13, S22, S23, S32, S33, S42, and S43 are ON. Accordingly, for example, one of the two electrodes of the capacitor C12 is connected to the terminal 203, the other of the two electrodes of the capacitor C12 and one of the two electrodes of the capacitor C15 are connected to the terminal 202, and the other of the two electrodes of the capacitor C15 is connected to the terminal 201.

Meanwhile, in the second phase, the switches S11, S14, S21, S24, S31, S34, S41, and S44 are ON. Accordingly, for example, one of the two electrodes of the capacitor C15 is connected to the terminal 203, the other of the two electrodes of the capacitor C15 and one of the two electrodes of the capacitor C12 are connected to the terminal 202, and the other of the two electrodes of the capacitor C12 is connected to the terminal 201.

By repeating the first phase and the second phase, for example, one of the capacitors C12 and C15 can be discharged to the capacitor C30 while the other of the capacitors C12 and C15 is being charged from the terminal 202. That is, the capacitors C12 and C15 can be charged and discharged in a complementary manner.

Like the set of the capacitors C12 and C15, each of the set of the capacitors C11 and C14 and the set of the capacitors C13 and C16 can also be charged and discharged in a complementary manner by repeating the first phase and the second phase.

Each of the capacitors C10, C20, C30, and C40 functions as a smoothing capacitor. That is, each of the capacitors C10, C20, C30, and C40 is configured for holding and smoothing the voltages V1 to V4 in the terminals 201 to 204.

The capacitor C10 is connected between the terminal 201 and the ground. According to an exemplary aspect, one of two electrodes of the capacitor C10 is connected to the terminal 201. Meanwhile, the other of the two electrodes of the capacitor C10 is connected to the ground.

The capacitor C20 is connected between the terminals 201 and 202. According to an exemplary aspect, one of two electrodes of the capacitor C20 is connected to the terminal 202. Meanwhile, the other of the two electrodes of the capacitor C20 is connected to the terminal 201.

The capacitor C30 is connected between the terminals 202 and 203. According to an exemplary aspect, one of two electrodes of the capacitor C30 is connected to the terminal 203. Meanwhile, the other of the two electrodes of the capacitor C30 is connected to the terminal 202.

The capacitor C40 is connected between the terminals 203 and 204. According to an exemplary aspect, one of two electrodes of the capacitor C40 is connected to the terminal 204. Meanwhile, the other of the two electrodes of the capacitor C40 is connected to the terminal 203.

The switch S11 is connected between one of the two electrodes of the capacitor C11 and the terminal 203. According to an exemplary aspect, one end of the switch S11 is connected to one of the two electrodes of the capacitor C11 through the terminal 211. Meanwhile, the other end of the switch S11 is connected to the terminal 203.

The switch S12 is connected between one of the two electrodes of the capacitor C11 and the terminal 204. According to an exemplary aspect, one end of the switch S12 is connected to one of the two electrodes of the capacitor C11 through the terminal 211. Meanwhile, the other end of the switch S12 is connected to the terminal 204.

The switch S21 is an example of a first switch and is connected between one of the two electrodes of the capacitor C12 and the terminal 202. According to an exemplary aspect, one end of the switch S21 is connected to one of the two electrodes of the capacitor C12 and the other of the two electrodes of the capacitor C11 through the terminal 212. Meanwhile, the other end of the switch S21 is connected to the terminal 202.

The switch S22 is an example of a third switch and is connected between one of the two electrodes of the capacitor C12 and the terminal 203. According to an exemplary aspect, one end of the switch S22 is connected to one of the two electrodes of the capacitor C12 and the other of the two electrodes of the capacitor C11 through the terminal 212. Meanwhile, the other end of the switch S22 is connected to the terminal 203.

The switch S31 is an example of a fourth switch and is connected between the other of the two electrodes of the capacitor C12 and the terminal 201. According to an exemplary aspect, one end of the switch S31 is connected to the other of the two electrodes of the capacitor C12 and one of the two electrodes of the capacitor C13 through the terminal 213. Meanwhile, the other end of the switch S31 is connected to the terminal 201.

The switch S32 is an example of a second switch and is connected between the other of the two electrodes of the capacitor C12 and the terminal 202. According to an exemplary aspect, one end of the switch S32 is connected to the other of the two electrodes of the capacitor C12 and one of the two electrodes of the capacitor C13 through the terminal 213. Meanwhile, the other end of the switch S32 is connected to the terminal 202. That is, the other end of the switch S32 is connected to the other end of the switch S21.

The switch S41 is connected between the other of the two electrodes of the capacitor C13 and the ground. According to an exemplary aspect, one end of the switch S41 is connected to the other of the two electrodes of the capacitor C13 through the terminal 214. Meanwhile, the other end of the switch S41 is connected to the ground.

The switch S42 is connected between the other of the two electrodes of the capacitor C13 and the terminal 201. According to an exemplary aspect, one end of the switch S42 is connected to the other of the two electrodes of the capacitor C13 through the terminal 214. Meanwhile, the other end of the switch S42 is connected to the terminal 201. That is, the other end of the switch S42 is connected to the other end of the switch S31.

The switch S13 is connected between one of the two electrodes of the capacitor C14 and the terminal 203. According to an exemplary aspect, one end of the switch S13 is connected to one of the two electrodes of the capacitor C14 through the terminal 215. Meanwhile, the other end of the switch S13 is connected to the terminal 203. That is, the other end of the switch S13 is connected to the other end of the switch S11 and the other end of the switch S22.

The switch S14 is connected between one of the two electrodes of the capacitor C14 and the terminal 204. According to an exemplary aspect, one end of the switch S14 is connected to one of the two electrodes of the capacitor C14 through the terminal 215. Meanwhile, the other end of the switch S14 is connected to the terminal 204. That is, the other end of the switch S14 is connected to the other end of the switch S12.

The switch S23 is an example of a fifth switch and is connected between one of the two electrodes of the capacitor C15 and the terminal 202. According to an exemplary aspect, one end of the switch S23 is connected to one of the two electrodes of the capacitor C15 and the other of the two electrodes of the capacitor C14 through the terminal 216. Meanwhile, the other end of the switch S23 is connected to the terminal 202. That is, the other end of the switch S23 is connected to the other end of the switch S21 and the other end of the switch S32.

The switch S24 is an example of a seventh switch and is connected between one of the two electrodes of the capacitor C15 and the terminal 203. According to an exemplary aspect, one end of the switch S24 is connected to one of the two electrodes of the capacitor C15 and the other of the two electrodes of the capacitor C14 through the terminal 216. Meanwhile, the other end of the switch S24 is connected to the terminal 203. That is, the other end of the switch S24 is connected to the other end of the switch S11, the other end of the switch S22, and the other end of the switch S13.

The switch S33 is an example of an eighth switch and is connected between the other of the two electrodes of the capacitor C15 and the terminal 201. According to an exemplary aspect, one end of the switch S33 is connected to the other of the two electrodes of the capacitor C15 and one of the two electrodes of the capacitor C16 through the terminal 217. Meanwhile, the other end of the switch S33 is connected to the terminal 201. That is, the other end of the switch S33 is connected to the other end of the switch S31 and the other end of the switch S42.

The switch S34 is an example of a sixth switch and is connected between the other of the two electrodes of the capacitor C15 and the terminal 202. According to an exemplary aspect, one end of the switch S34 is connected to the other of the two electrodes of the capacitor C15 and one of the two electrodes of the capacitor C16 through the terminal 217. Meanwhile, the other end of the switch S34 is connected to the terminal 202. That is, the other end of the switch S34 is connected to the other end of the switch S21, the other end of the switch S32, and the other end of the switch S23.

The switch S43 is connected between the other of the two electrodes of the capacitor C16 and the ground. According to an exemplary aspect, one end of the switch S43 is connected to the other of the two electrodes of the capacitor C16 through the terminal 218. Meanwhile, the other end of the switch S43 is connected to the ground.

The switch S44 is connected between the other of the two electrodes of the capacitor C16 and the terminal 201. According to an exemplary aspect, one end of the switch S44 is connected to the other of the two electrodes of the capacitor C16 through the terminal 218. Meanwhile, the other end of the switch S44 is connected to the terminal 201. That is, the other end of the switch S44 is connected to the other end of the switch S31, the other end of the switch S42, and the other end of the switch S33.

A first set of switches including the switches S12, S13, S22, S23, S32, S33, S42, and S43 and a second set of switches including the switches S11, S14, S21, S24, S31, S34, S41, and S44 are switched ON and OFF in a complementary manner. According to an exemplary aspect, in the first phase, the first set of switches is ON, and the second set of switches is OFF. Conversely, in the second phase, the first set of switches is OFF, and the second set of switches is ON.

For example, charging of the capacitors C10 to C40 from the capacitors C11 to C13 is executed in one of the first phase and the second phase, and charging of the capacitors C10 to C40 from the capacitors C14 to C16 is executed in the other of the first phase and the second phase. That is, the capacitors C10 to C40 are always charged from the capacitors C11 to C13 or from the capacitors C14 to C16. Thus, even in a case where a current flows at a high speed from the terminals 201 to 204 to the supply modulators 30A and 30B, a change in potentials of the terminals 201 to 204 can be suppressed because the terminals 201 to 204 are supplemented with charges at a high speed.

The switched-capacitor circuit 20, by operating in the above manner, can maintain almost equal voltages at both ends of each of the capacitors C10, C20, C30, and C40. According to an exemplary aspect, the voltages V1 to V4 (voltages with respect to the ground potential) satisfying V1:V2:V3:V4=1:2:3:4 are maintained in four nodes labeled V1 to V4. Voltage levels of the voltages V1 to V4 correspond to the plurality of discrete voltage levels that can be supplied to the supply modulators 30A and 30B by the switched-capacitor circuit 20.

It is noted that the voltage ratio V1:V2:V3:V4 is not limited to 1:2:3:4. For example, the voltage ratio V1:V2:V3:V4 may be 1:2:4:8 in an alternative aspect.

In addition, the configuration of the switched-capacitor circuit 20 illustrated in FIG. 2A is an example, and the present disclosure is not limited thereto. While the switched-capacitor circuit 20 is configured to supply voltages of four discrete voltage levels in FIG. 2A, the present disclosure is not limited thereto. The switched-capacitor circuit 20 may be configured to supply voltages of any number of discrete voltage levels of two or more. For example, in the case of supplying voltages of two discrete voltage levels, the switched-capacitor circuit 20 may include at least the capacitors C12 and C15 and the switches S21 to S24 and S31 to S34.

### [1.2.2 Circuit Configurations of Supply Modulators 30A and 30B]

Next, the circuit configurations of the supply modulators 30A and 30B will be described. The supply modulator 30A is connected to the digital control circuit 60. As illustrated in FIG. 2A, the supply modulator 30A includes terminals 130A to 134A and switches S51A to S54A. In addition, the supply modulator 30B is connected to the digital control circuit 60. As illustrated in FIG. 2A, the supply modulator 30B includes terminals 130B to 134B and switches S51B to S54B.

Hereinafter, the supply modulator 30A will be described, and description of the supply modulator 30B will be omitted because description of the supply modulator 30B is approximately the same as description of the supply modulator 30A in which reference numeral “A” is replaced with “B”. The supply modulator 30B may be integrated into the supply modulator 30A.

The terminal 130A is an example of a third power supply terminal and is connected to the switches S51A to S54A included in the supply modulator 30A and the filter circuit 40A. The terminal 130A is an output terminal for supplying a voltage selected from the voltages V1 to V4 to the filter circuit 40A.

Each of the terminals 131A to 134A is an example of a seventh power supply terminal and is connected to the switches included in the supply modulator 30A. The terminals 131A to 134A are connected to the terminals 201 to 204 of the switched-capacitor circuit 20, respectively. The terminals 131A to 134A are input terminals for receiving the voltages V4 to V1 from the switched-capacitor circuit 20.

The switch S51A is connected between the terminal 131A and the terminal 130A. In this connection configuration, the switch S51A can be switched ON/OFF using a control signal S3A to switch between a connected state and a disconnected state between the terminal 131A and the terminal 130A.

The switch S52A is an example of a tenth switch and is connected between the terminal 132A and the terminal 130A. In this connection configuration, the switch S52A can be switched ON/OFF using the control signal S3A to switch between a connected state and a disconnected state between the input terminal 132A and the output terminal 130A.

The switch S53A is an example of a ninth switch and is connected between the terminal 133A and the terminal 130A. In this connection configuration, the switch S53A can be switched ON/OFF using the control signal S3A to switch between a connected state and a disconnected state between the terminal 133A and the terminal 130A.

The switch S54A is connected between the terminal 134A and the terminal 130A. In this connection configuration, the switch S54A can be switched ON/OFF using the control signal S3A to switch between a connected state and a disconnected state between the input terminal 134A and the output terminal 130A.

The switches S51A to S54A are controlled to be exclusively ON. That is, only one of the switches S51A to S54A is ON, and the rest of the switches S51A to S54A are OFF. Accordingly, the supply modulator 30A can output one voltage selected from the voltages V1 to V4.

The configuration of the supply modulator 30A illustrated in FIG. 2A is an example, and the present disclosure is not limited thereto. Particularly, the switches S51A to S54A may have any configurations as long as any of the four terminals 131A to 134A may be selected and connected to the terminal 130A. For example, the supply modulator 30A may further include a switch connected between the switches S51A to S53A, and the switch S54A and the terminal 130A. In addition, for example, the supply modulator 30A may further include a switch connected between the switches S51A and S52A, and the switches S53A and S54A and the terminal 130A.

In a case where voltages of two discrete voltage levels are supplied from the switched-capacitor circuit 20, the supply modulator 30A may include at least the switches S52A and S53A.

### [1.2.3 Circuit Configuration of Pre-Regulator Circuit 10]

First, a configuration of the pre-regulator circuit 10 will be described. As illustrated in FIG. 2A, the pre-regulator circuit 10 includes an input terminal 110, terminals 111 to 116, switches S61 to S63, S71, and S72, a power inductor L71, and capacitors C61 to C64.

The input terminal 110 is an input terminal of a direct current voltage. That is, the input terminal 110 is a terminal for receiving the input voltage from the direct current power source 50.

The terminal 111 is an example of a fourth power supply terminal and is connected to the switch S61. The terminal 111 is an output terminal of the voltage V4. That is, the terminal 111 is an output terminal for supplying the voltage V4 to the switched-capacitor circuit 20. The terminal 111 is connected to the terminal 204 of the switched-capacitor circuit 20.

The terminal 112 is an example of the fourth power supply terminal and is connected to the switch S62. The terminal 112 is an output terminal of the voltage V3. That is, the terminal 112 is an output terminal for supplying the voltage V3 to the switched-capacitor circuit 20. The terminal 112 is connected to the terminal 203 of the switched-capacitor circuit 20.

The terminal 113 is an example of the fourth power supply terminal and is connected to the switch S63. The terminal 113 is an output terminal of the voltage V2. That is, the terminal 113 is an output terminal for supplying the voltage V2 to the switched-capacitor circuit 20. The terminal 113 is connected to the terminal 202 of the switched-capacitor circuit 20.

The terminal 114 is an output terminal of the voltage V1. That is, the terminal 114 is an output terminal for supplying the voltage V1 to the switched-capacitor circuit 20. The terminal 114 is connected to the terminal 201 of the switched-capacitor circuit 20.

The terminal 115 is an example of a first power supply terminal and is a terminal for inductor connection. The terminal 115 is connected to one end of the power inductor L71 and is connected to the switches S71 and S72.

The terminal 116 is an example of the first power supply terminal and is a terminal for inductor connection. The terminal 116 is connected to the other end of the power inductor L71 and is connected to the switches S61 to S63.

The switch S71 is an example of an eleventh switch and is connected between the input terminal 110 and the terminal 115 connected to one end of the power inductor L71. In this connection configuration, the switch S71 can be switched ON/OFF to switch between a connected state and a disconnected state between the input terminal 110 and one end of the power inductor L71.

The switch S72 is an example of a twelfth switch and is connected between the terminal 115 connected to one end of the power inductor L71 and the ground. In this connection configuration, the switch S72 can be switched ON/OFF to switch between a connected state and a disconnected state between one end of the power inductor L71 and the ground.

The switch S61 is connected between the terminal 116 connected to the other end of the power inductor L71 and the terminal 111. In this connection configuration, the switch S61 can be switched ON/OFF to switch between a connected state and a disconnected state between the other end of the power inductor L71 and the terminal 111.

The switch S62 is connected between the terminal 116 connected to the other end of the power inductor L71 and the terminal 112. In this connection configuration, the switch S62 can be switched ON/OFF to switch between a connected state and a disconnected state between the other end of the power inductor L71 and the output terminal 112.

The switch S63 is connected between the terminal 116 connected to the other end of the power inductor L71 and the terminal 113. In this connection configuration, the switch S63 can be switched ON/OFF to switch between a connected state and a disconnected state between the other end of the power inductor L71 and the terminal 113.

One of two electrodes of the capacitor C61 is connected to the switch S61 and the terminal 111. The other of the two electrodes of the capacitor C61 is connected to the switch S62, the terminal 112, and one of two electrodes of the capacitor C62.

One of the two electrodes of the capacitor C62 is connected to the switch S62, the terminal 112, and the other of the two electrodes of the capacitor C61. The other of the two electrodes of the capacitor C62 is connected to a path connecting the switch S63, the terminal 113, and one of two electrodes of the capacitor C63.

One of the two electrodes of the capacitor C63 is connected to the switch S63, the terminal 113, and the other of the two electrodes of the capacitor C62. The other of the two electrodes of the capacitor C63 is connected to the terminal 114 and one of two electrodes of the capacitor C64.

One of the two electrodes of the capacitor C64 is connected to the terminal 114 and the other of the two electrodes of the capacitor C63. The other of the two electrodes of the capacitor C64 is connected to the ground.

The switches S61 to S63 are controlled to be exclusively ON. That is, only one of the switches S61 to S63 is ON, and the rest of the switches S61 to S63 are OFF. By causing only one of the switches S61 to S63 to be ON, the pre-regulator circuit 10 can change the voltage to be supplied to the switched-capacitor circuit 20 among the voltage levels of the voltages V2 to V4.

The pre-regulator circuit 10 configured in the above manner can supply charges to the switched-capacitor circuit 20 through at least one of the terminals 111 to 113.

In a case where the input voltage is converted into one first voltage, the pre-regulator circuit 10 may include at least the switches S71 and S72 and the power inductor L71.

### [1.2.4 Circuit Configurations of Filter Circuits 40A and 40B]

Next, the circuit configurations of the filter circuits 40A and 40B will be described. The filter circuits 40A and 40B include a low pass filter (LPF). According to an exemplary aspect, as illustrated in FIG. 2A, the filter circuit 40A includes inductors L51A to L53A, capacitors C51A and C52A, a resistor R51A, an input terminal 140A, and an output terminal 141A. In addition, the filter circuit 40B includes inductors L51B to L53B, capacitors C51B and C52B, a resistor R51B, an input terminal 140B, and an output terminal 141B. Hereinafter, the filter circuit 40A will be described, and description of the filter circuit 40B will be omitted because description of the filter circuit 40B is approximately the same as description of the filter circuit 40A in which reference numeral “A” is replaced with “B”.

The input terminal 140A is an input terminal of the voltage selected by the supply modulator 30A. That is, the input terminal 140A is a terminal for receiving the voltage selected from the plurality of voltages V1 to V4.

The output terminal 141A is an output terminal of the power supply voltage V_{ETA} . That is, the output terminal 141A is a terminal for supplying the power supply voltage V_{ETA} to the power amplifier 2A.

In an exemplary aspect, the inductors L51A to L53A, the capacitors C51A and C52A, and the resistor R51A form a low pass filter. Accordingly, the filter circuit 40A reduces a radio frequency component included in the power supply voltage. For example, in a case where a predetermined band is a frequency band for frequency division duplex (FDD), the filter circuit 40A is configured to reduce a frequency component of a gap between an uplink operation band and a downlink operation band of the predetermined band.

The configuration of the filter circuit 40A illustrated in FIG. 2A is an example, and the present disclosure is not limited thereto. For example, it is possible that the filter circuit 40A does not include the inductor L53A or the resistor R51A. In addition, for example, the filter circuit 40A may include an inductor connected to one of two electrodes of the capacitor C51A or may include an inductor connected to one of two electrodes of the capacitor C52A.

### [1.2.5 Circuit Configuration of Digital Control Circuit 60]

Next, the circuit configuration of the digital control circuit 60 will be described. As illustrated in FIG. 2B, the digital control circuit 60 includes a first controller 61, a second controller 62, capacitors C81 and C82, and terminals 601 to 606.

The terminals 601 and 602 are control terminals for receiving a source-synchronous digital control signal from the RFIC 5. According to an exemplary aspect, the terminal 601 is a terminal for receiving a clock signal from the RFIC 5, and the terminal 602 is a terminal for receiving a data signal from the RFIC 5.

Each of the terminals 603 to 606 is an example of a control terminal and is a control terminal for receiving a digital control logic/line (DCL) signal corresponding to the envelope signal from the RFIC 5. According to an exemplary aspect, the terminals 603 and 604 are terminals for receiving DCL signals (DCL1A and DCL2A) for controlling the supply modulator 30A, and the terminals 605 and 606 are terminals for receiving DCL signals (DCL1B and DCL2B) for controlling the supply modulator 30B.

Each of the DCL signals (DCLIA, DCL2A, DCL1B, and DCL2B) is a 1-bit signal. Each of the voltages V1 to V4 is represented by a combination of two 1-bit signals. For example, V1, V2, V3, and V4 are represented by “00”, “01”, “10”, and “11”, respectively. In some exemplary embodiments, a gray code is used for representing the voltage level.

The first controller 61 can generate control signals S1 and S2 by processing the source-synchronous digital control signal received from the RFIC 5 through the terminals 601 and 602. The control signal S1 is a signal for controlling ON/OFF of the switches S61 to S63, S71, and S72 included in the pre-regulator circuit 10. The control signal S2 is a signal for controlling ON/OFF of the switches S11 to S14, S21 to S24, S31 to S34, and S41 to S44 included in the switched-capacitor circuit 20.

The digital control signal processed by the first controller 61 is not limited to the source-synchronous digital control signal. For example, the first controller 61 may process a clock-embedded digital control signal.

In addition, while one set of the clock signal and the data signal is used as the digital control signal for the pre-regulator circuit 10 and the switched-capacitor circuit 20 in the present exemplary embodiment, the present disclosure is not limited thereto. For example, sets of the clock signal and the data signal may be individually used as the digital control signal for the pre-regulator circuit 10 and the switched-capacitor circuit 20.

The second controller 62 generates the control signal S3A by processing the DCL signals (DCL1A and DCL2A) received from the RFIC 5 through the terminals 603 and 604. The DCL signals (DCL1A and DCL2A) correspond to a first envelope signal. The control signal S3A is a signal for controlling ON/OFF of the switches S51A to S54A included in the supply modulator 30A.

Furthermore, the second controller 62 generates a control signal S3B by processing the DCL signals (DCL1B and DCL2B) received from the RFIC 5 through the terminals 605 and 606. The DCL signals (DCLIB and DCL2B) correspond to a second envelope signal. The control signal S3B is a signal for controlling ON/OFF of the switches S51B to S54B included in the supply modulator 30B.

The capacitor C81 is connected between the first controller 61 and the ground. For example, the capacitor C81 is connected between a power supply line for supplying power to the first controller 61 and the ground and functions as a bypass capacitor. The capacitor C82 is connected between the second controller 62 and the ground.

While two DCL signals are used for controlling the supply modulator 30A and two DCL signals are used for controlling the supply modulator 30B in the present exemplary embodiment, the number of DCL signals is not limited thereto. For example, one DCL signal may be used, or any number of DCL signals of three or more may be used, in accordance with the number of voltage levels selectable by each of the supply modulators 30A and 30B. In addition, the digital control signal used for controlling the supply modulators 30A and 30B is not limited to the DCL signal.

### [2 Description of Digital ET Mode]

Here, the digital ET mode will be described in comparison with an ET mode in the related art (hereinafter, referred to as an analog ET mode) with reference to FIGS. 3A and 3B. FIG. 3A is a graph illustrating an example of a trend of the power supply voltage in the digital ET mode. FIG. 3B is a graph illustrating an example of a trend of the power supply voltage in the analog ET mode. In FIGS. 3A and 3B, a horizontal axis represents time, and a vertical axis represents a voltage. In addition, a thick solid line represents the power supply voltage, and a thin solid line (waveform) represents the modulated signal.

In the digital ET mode, as illustrated in FIG. 3A, an envelope of the modulated signal is tracked by changing the power supply voltage to the plurality of discrete voltage levels in one frame. Consequently, the power supply voltage signal forms a rectangular wave. In the digital ET mode, the power supply voltage level is selected or set from the plurality of discrete voltage levels based on the envelope signal.

In an exemplary aspect, a frame means a unit forming the radio frequency signal (modulated signal). For example, in 5G NR or LTE, a frame includes 10 subframes, each subframe includes a plurality of slots, and each slot includes a plurality of symbols. A subframe length is 1 ms, and a frame length is 10 ms.

In the analog ET mode, as illustrated in FIG. 3B, the envelope of the modulated signal is tracked by continuously changing the power supply voltage. In the analog ET mode, the power supply voltage is determined based on the envelope signal. In the analog ET mode, it is difficult for the power supply voltage to track the envelope in a case where the envelope of the modulated signal changes at a high speed.

### EXAMPLE

### [3 Component Disposition]

### [3.1 Component Disposition of Tracker Module 100]

Next, a tracker module 100 on which the pre-regulator circuit 10 (excluding the power inductor L71), the switched-capacitor circuit 20, the supply modulators 30A and 30B, the filter circuits 40A and 40B, and the digital control circuit 60 are mounted will be described with reference to FIGS. 4 to 7 as an example of the power supply circuit 1 configured in the above manner. While the power inductor L71 included in the pre-regulator circuit 10 is not disposed on a module laminate 90 and is not included in the tracker module 100 in the present example, the present disclosure is not limited thereto.

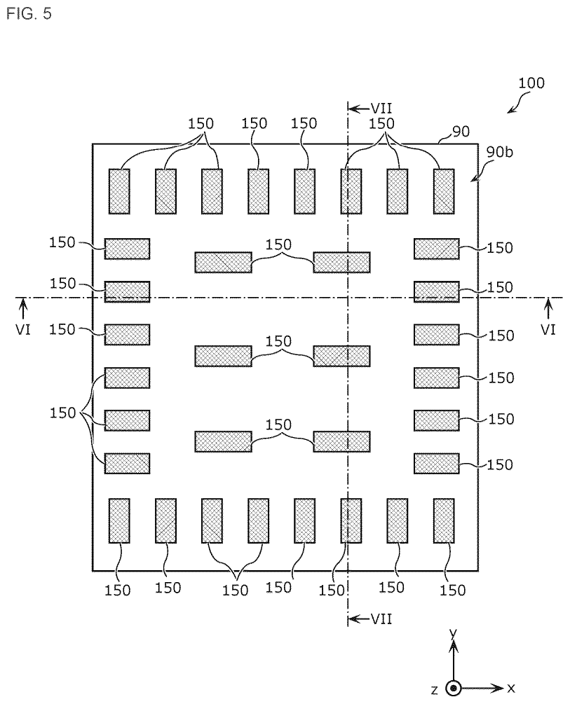

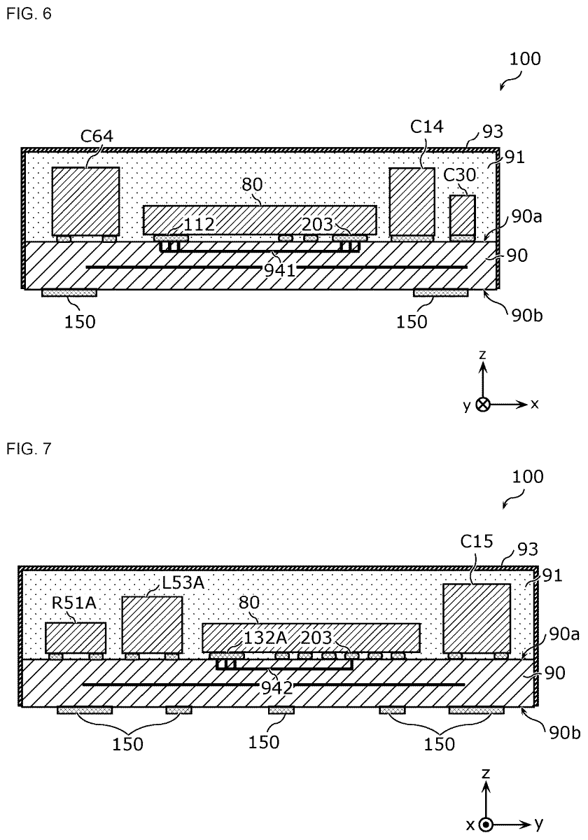

FIG. 4 is a plan view of the tracker module 100 according to the present example. FIG. 5 is a plan view of the tracker module 100 according to the present example and is a view in which a main surface 90b side of the module laminate 90 is seen transparently from the positive side of the z-axis. FIGS. 6 and 7 are cross-sectional views of the tracker module 100 according to the present example. The cross section of the tracker module 100 in FIG. 6 is a cross section taken along a line V1-V1 in FIGS. 4 and 5. The cross section of the tracker module 100 in FIG. 7 is a cross section taken along a line VII-VII in FIGS. 4 and 5.

In FIGS. 4 to 6, a part of wires connecting a plurality of circuit components disposed on the module laminate 90 is omitted. In addition, in FIGS. 4 and 5, a resin member 91 covering the plurality of circuit components and a shield electrode layer 93 covering a surface of the resin member 91 are not illustrated.

The tracker module 100 includes the module laminate 90, the resin member 91, the shield electrode layer 93, circuit components X11, X12, X51 to X56, and X81, and a plurality of land electrodes 150, in addition to the plurality of circuit components (excluding the power inductor L71) including active elements and passive elements included in the pre-regulator circuit 10, the switched-capacitor circuit 20, the supply modulators 30A and 30B, the filter circuits 40A and 40B, and the digital control circuit 60 illustrated in FIGS. 2A and 2B.

The module laminate 90 has main surfaces 90a and 90b that face each other. The main surfaces 90a and 90b are examples of a first main surface and a second main surface, respectively. In the module laminate 90, a wiring layer, a via conductor, a ground plane, and the like are formed. While the module laminate 90 has a rectangular shape in the plan view in FIGS. 4 and 5, the present disclosure is not limited to the shape.

The module laminate 90 includes wires 941 and 942. The wire 941 is an example of a first wire and connects the terminals 112 and 203 of an integrated circuit 80 to an outside of the integrated circuit 80, as illustrated in FIG. 6. The wire 942 is an example of a second wire and connects the terminals 132A and 203 of the integrated circuit 80 to the outside of the integrated circuit 80, as illustrated in FIG. 7. While the wires 941 and 942 are formed in the module laminate 90 in FIGS. 6 and 7, the present disclosure is not limited thereto. The wire 941 and/or 942 may be formed on a surface (for example, the main surface 90a or 90b) of the module laminate 90.

For example, a low temperature co-fired ceramics (LTCC) laminate, a high temperature co-fired ceramics (HTCC) laminate, a component-embedded board, a laminate having a redistribution layer (RDL), or a printed circuit board having a laminated structure of a plurality of dielectric layers can be used as the module laminate 90. However, the present disclosure is not limited thereto.

The integrated circuit 80, the capacitors C10 to C16, C20, C30, C40, C51A, C51B, C52A, C52B, C61 to C64, C81, and C82, the inductors L51A to L53A and L51B to L53B, the resistors R51A and R51B, the circuit components X11, X12, X51 to X56, and X81, and the resin member 91 are disposed on the main surface 90a.

The integrated circuit 80 includes a PR switch portion 80a, an SC switch portion 80b, an OS switch portion 80c, and a digital control portion 80d. The PR switch portion 80a is an example of a first switch portion and includes the switches S61 to S63, S71, and S72. The SC switch portion 80b is an example of a second switch portion and includes the switches S11 to S14, S21 to S24, S31 to S34, and S41 to S44. The OS switch portion 80c is an example of a third switch portion and includes the switches S51A to S54A and S51B to S54B. The digital control portion 80d includes the first controller 61 and the second controller 62.

While the PR switch portion 80a, the SC switch portion 80b, the OS switch portion 80c, and the digital control portion 80d are included in one integrated circuit 80 in FIG. 4, the present disclosure is not limited thereto. For example, the PR switch portion 80a and the SC switch portion 80b may be included in one integrated circuit, and the OS switch portion 80c may be included in another integrated circuit. In addition, for example, the SC switch portion 80b and the OS switch portion 80c may be included in one integrated circuit, and the PR switch portion 80a may be included in another integrated circuit. In addition, the PR switch portion 80a and the OS switch portion 80c may be included in one integrated circuit, and the SC switch portion 80b may be included in another integrated circuit. In addition, for example, the PR switch portion 80a, the SC switch portion 80b, and the OS switch portion 80c may be individually included in three integrated circuits. In this case, the digital control portion 80d may be included in each of the plurality of integrated circuits or may be included in only any of the plurality of integrated circuits.

In addition, while the integrated circuit 80 has a rectangular shape in the plan view of the module laminate 90 in FIG. 4, the present disclosure is not limited to the shape.

The integrated circuit 80 is configured using, for example, a complementary metal oxide semiconductor (CMOS) and According to an exemplary aspect, may be manufactured through a silicon on insulator (SOI) process. The integrated circuit 80 is not limited to the CMOS.

In an exemplary aspect, each of the capacitors C10 to C16, C20, C30, C40, C51A, C52A, C51B, C52B, C61 to C64, C81, and C82 is mounted as a chip capacitor. Moreover, a chip capacitor can be a surface mount device (SMD) forming a capacitor. Mounting of the plurality of capacitors is not limited to the chip capacitor. For example, a part or all of the plurality of capacitors may be included in an integrated passive device (IPD) or may be included in the integrated circuit 80 in an alternative aspect.

In an exemplary aspect, each of the inductors L51A to L53A and L51B to L53B is mounted as a chip inductor. Moreover, a chip inductor can be an SMD forming an inductor. It is noted that mounting of the plurality of inductors is not limited to the chip inductor. For example, the plurality of inductors may be included in an IPD.

In an exemplary aspect, each of the resistors R51A and R51B is mounted as a chip resistor that can be an SMD forming a resistor. It is noted that mounting of the resistors R51A and R51B is not limited to the chip resistor. For example, the resistors R51A and R51B may be included in an IPD.

Accordingly, the plurality of capacitors, the plurality of inductors, and the plurality of resistors disposed on the main surface 90a are disposed in groups for each circuit around the integrated circuit 80.

In the plan view of the module laminate 90, a group of the capacitors C61 to C64 included in the pre-regulator circuit 10 is disposed in a region interposed between a straight line along a left edge of the integrated circuit 80 and a straight line along a left edge of the module laminate 90 on the main surface 90a. Accordingly, the group of the circuit components included in the pre-regulator circuit 10 is disposed close to the PR switch portion 80a in the integrated circuit 80.

In the plan view of the module laminate 90, a group of the capacitors C10 to C16, C20, C30, and C40 included in the switched-capacitor circuit 20 is disposed in a region interposed between a straight line along an upper edge of the integrated circuit 80 and a straight line along an upper edge of the module laminate 90 on the main surface 90a and in a region interposed between the straight line along a right edge of the integrated circuit 80 and a straight line along a right edge of the module laminate 90 on the main surface 90a. Accordingly, the group of the circuit components included in the switched-capacitor circuit 20 is disposed close to the SC switch portion 80b in the integrated circuit 80. That is, the SC switch portion 80b is disposed closer to the switched-capacitor circuit 20 than each of the PR switch portion 80a and the OS switch portion 80c.

In the plan view of the module laminate 90, a group of the capacitors C51A, C51B, C52A, and C52B, the inductors L51A to L53A and L51B to L53B, and the resistors R51A and R51B included in the filter circuits 40A and 40B is disposed in a region interposed between a straight line along a lower edge of the integrated circuit 80 and a straight line along a lower edge of the module laminate 90 on the main surface 90a. Accordingly, the group of the circuit components included in the filter circuits 40A and 40B is disposed close to the OS switch portion 80c in the integrated circuit 80. That is, the OS switch portion 80c is disposed closer to the filter circuits 40A and 40B than each of the PR switch portion 80a and the SC switch portion 80b.

In the plan view of the module laminate 90, a group of the capacitors C81 and C82 included in the digital control circuit 60 is disposed in the region interposed between the straight line along the left edge of the integrated circuit 80 and the straight line along the left edge of the module laminate 90 on the main surface 90a.

The circuit components X11, X12, X51 to X56, and X81 are any circuit components that are not essential to the present example.

The resin member 91 covers the main surface 90a and at least a part of the plurality of electronic components on the main surface 90a. The resin member 91 has a function of securing reliability such as mechanical strength and humidity resistance of the plurality of electronic components on the main surface 90a. It is possible that the resin member 91 is not included in the tracker module 100.

The plurality of land electrodes 150 are disposed on the main surface 90b. The plurality of land electrodes 150 are electrically connected to an input-output terminal and/or a ground terminal or the like on a motherboard (not illustrated) disposed in the negative direction of the z-axis in the tracker module 100. In addition, the plurality of the land electrodes 150 are electrically connected to the plurality of circuit components disposed on the main surface 90a through a via conductor or the like formed in the module laminate 90.

While copper electrodes can be used as the plurality of land electrodes 150, the present disclosure is not limited thereto. For example, solder electrodes may be used as the plurality of land electrodes 150. In addition, a plurality of bump electrodes or a plurality of post electrodes may be used as the plurality of external connection terminals instead of the plurality of land electrodes 150.

The shield electrode layer 93 is a thin metal film formed using, for example, sputtering. The shield electrode layer 93 is formed to cover surfaces (an upper surface and side surfaces) of the resin member 91. The shield electrode layer 93 is connected to the ground and suppresses permeation of external noise into the electronic components forming the tracker module 100 and interference of noise generated in the tracker module 100 with other modules or other devices. The shield electrode layer 93 may not be included in the tracker module 100 in an alternative aspect.

The configuration of the tracker module 100 according to the present example is an example, and the present disclosure is not limited thereto. For example, a part of the capacitors and the inductors disposed on the main surface 90a may be formed in the module laminate 90. In addition, it is possible that a part of the capacitors and the inductors disposed on the main surface 90a is not included in the tracker module or is not disposed on the module laminate 90.

### [3.2 Shapes and Disposition of Terminals of Integrated Circuit 80]

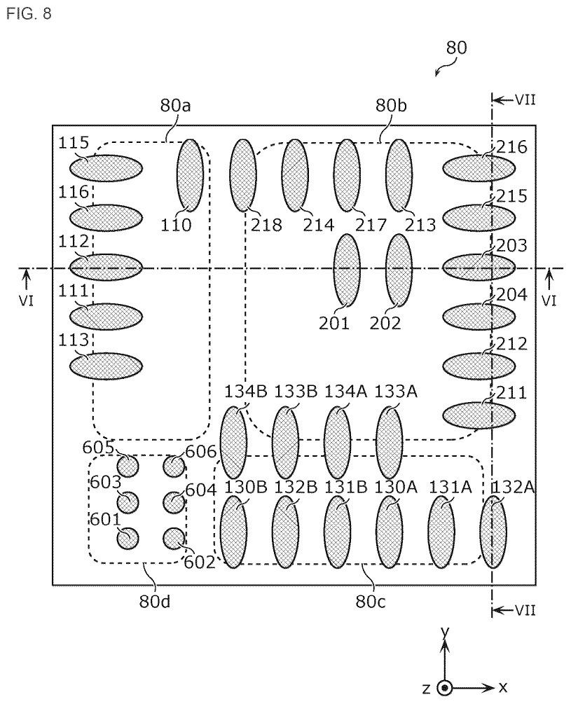

Next, terminals of the integrated circuit 80 will be described with reference to FIG. 8. FIG. 8 is a disposition diagram of the terminals of the integrated circuit 80 according to the example. According to an exemplary aspect, FIG. 8 is a view in which the terminals of the integrated circuit 80 are seen transparently from the positive side of the z-axis.

Each of the terminals 111 to 113 is an example of the fourth power supply terminal. At least a part of each of the terminals 111 to 113 overlaps at least a part of the PR switch portion 80a in the plan view of the module laminate 90.

As illustrated in FIG. 6, the terminal 112 is connected to the terminal 203 through the wire 941 of the module laminate 90. Like the terminal 112, the terminals 111 and 113 may also be connected to the terminals 204 and 202, respectively, through a wire (not illustrated) of the module laminate 90.

Each of the terminals 115 and 116 is an example of the first power supply terminal. At least a part of each of the terminals 115 and 116 overlaps at least a part of the PR switch portion 80a in the plan view of the module laminate 90.

Each of the terminals 130A and 130B is an example of the third power supply terminal. At least a part of each of the terminals 130A and 130B overlaps at least a part of the OS switch portion 80c in the plan view of the module laminate 90.

Each of the terminals 131A to 134A and 131B to 134B is an example of the seventh power supply terminal and has an elongated shape (e.g., an oval shape with different radius in two axis directions) in the plan view of the module laminate 90. At least a part of each of the terminals 131A to 134A and 131B to 134B overlaps at least a part of the OS switch portion 80c in the plan view of the module laminate 90.

As illustrated in FIG. 7, the terminal 132A is connected to the terminal 203 through the wire 942 of the module laminate 90. Similarly, the terminal 132B is also connected to the terminal 203 through a wire (not illustrated) of the module laminate 90. Like the terminal 132A, the terminals 131A, 133A, and 134A may also be connected to the terminals 204, 202, and 201, respectively, through a wire (not illustrated) of the module laminate 90. Furthermore, the terminals 131B, 133B, and 134B may also be connected to the terminals 204, 202, and 201, respectively, through a wire (not illustrated) of the module laminate 90.

Each of the terminals 201 to 204 is an example of the fifth power supply terminal and the sixth power supply terminal. At least a part of each of the terminals 201 to 204 overlaps at least a part of the SC switch portion 80b in the plan view of the module laminate 90.

Each of the terminals 211 to 218 is an example of the second power supply terminal. At least a part of each of the terminals 211 to 218 overlaps at least a part of the SC switch portion 80b in the plan view of the module laminate 90.

Each of the terminals 603 to 606 is an example of the control terminal. At least a part of each of the terminals 603 to 606 overlaps at least a part of the digital control portion 80d in the plan view of the module laminate 90.

Bump electrodes made of gold, copper, aluminum, or an alloy including gold, copper or aluminum can be used as the terminals of the integrated circuit 80. Materials of the terminals are not limited thereto.

Each of the power supply terminals (terminals 111 to 113, 115, 116, 130A to 134A, 130B to 134B, 201 to 204, and 211 to 218) has an elongated shape in the plan view of the module laminate 90. The elongated shape means a shape that is long in a longitudinal direction. More specifically, the elongated shape means a shape of which a length in the longitudinal direction is greater than a length in a short direction orthogonal to the longitudinal direction. Meanwhile, each of the control terminals (terminals 603 to 606) has a circular shape in the plan view of the module laminate 90.

Each of the power supply terminals is larger than each of the control terminals in the plan view of the module laminate 90. That is, an area of a region of each power supply terminal orthogonally projected to the xy plane is larger than an area of a region of each control terminal orthogonally projected to the xy plane. The areas of the regions of the terminals orthogonally projected to the xy plane can be specified by recognizing the regions of the terminals in an image of the tracker module 100 captured by irradiating the tracker module 100 with an X-ray from a direction (z direction) orthogonal to the main surface 90a of the module laminate 90.

In addition, at least one of the power supply terminals is closer to a periphery of the integrated circuit 80 than the control terminals. According to an exemplary aspect, the terminals 111 to 113, 115, 116, 130A to 132A, 130B to 132B, 203, 204, and 211 to 218 are closer to the periphery of the integrated circuit 80 than the terminals 603 to 606. In FIG. 8, the terminals 111 to 113, 115, 116, 130A to 132A, 130B to 132B, 203, 204, and 211 to 218 are disposed along the periphery of the integrated circuit 80 in the plan view of the module laminate 90. More specifically, the terminals 111 to 113, 115, and 116 are arranged along the left edge of the integrated circuit 80 in the plan view of the module laminate 90, and longitudinal directions of the terminals 111 to 113, 115, and 116 are orthogonal to the left edge. The terminals 213, 214, 217, and 218 are arranged along the upper edge of the integrated circuit 80 in the plan view of the module laminate 90, and longitudinal directions of the terminals 213, 214, 217, and 218 are orthogonal to the upper edge. The terminals 203, 204, 211, 212, 215, and 216 are arranged along the right edge of the integrated circuit 80 in the plan view of the module laminate 90, and longitudinal directions of the terminals 203, 204, 211, 212, 215, and 216 are orthogonal to the right edge. The terminals 130A to 132A and 130B to 132B are arranged along the lower edge of the integrated circuit 80 in the plan view of the module laminate 90, and longitudinal directions of the terminals 130A to 132A and 130B to 132B are orthogonal to the lower edge. That is, the terminals 111 to 113, 115, 116, 130A to 132A, 130B to 132B, 203, 204, and 211 to 218 are disposed in a peripheral portion of the integrated circuit 80 in the plan view of the module laminate 90.

### [4 Effect and Like]

As described above, the tracker module 100 according to the present example includes the module laminate 90 and the integrated circuit 80 disposed on the module laminate 90. The integrated circuit 80 includes at least one switch included in the pre-regulator circuit 10 that is configured to convert the input voltage into the first voltage, at least one switch included in the switched-capacitor circuit 20 that is configured to generate the plurality of second voltages having the plurality of respective discrete voltage levels from the first voltage, at least one switch included in the supply modulator 30A or 30B that is configured to select at least one of the plurality of second voltages based on the DCL signal corresponding to the envelope signal, a power supply terminal connected to at least one of the at least one switch included in the pre-regulator circuit 10, the at least one switch included in the switched-capacitor circuit 20, and the at least one switch included in the supply modulator 30A or 30B, and a control terminal (for example, the terminal 603 or 604) that receives the DCL signal. In the plan view of the module laminate 90, the power supply terminal is larger than the control terminal.

According to this, heat in the integrated circuit 80 can be effectively transmitted to the module laminate 90 through the power supply terminal which is larger, and characteristic deterioration caused by heat can be suppressed. Particularly, in the switches included in the pre-regulator circuit 10, the switched-capacitor circuit 20, or the supply modulator 30A or 30B, since a higher current than a current in the digital control circuit 60 flows, heat generation caused by a switching loss is increased. By forming the power supply terminal connected to a heat source to be larger than the control terminal, heat dissipation of the integrated circuit 80 can be effectively improved in a limited mounting area.

In addition, for example, in the tracker module 100 according to the present example, the power supply terminal may include the first power supply terminal (for example, the terminal 115 or 116) that connects the power inductor L71 and at least one of the capacitors C61 to C64 included in the pre-regulator circuit 10 to the at least one switch included in the pre-regulator circuit 10. In the plan view of the module laminate 90, the first power supply terminal may be larger than the control terminal.

According to this, heat in the integrated circuit 80 can be effectively transmitted to the module laminate 90 through the first power supply terminal which is larger, and characteristic deterioration caused by heat can be suppressed. Particularly, in a case where the power supply voltage is supplied to a plurality of power amplifiers, a higher current flows in the switch included in the pre-regulator circuit 10, and a larger amount of heat is generated. Accordingly, by forming the first power supply terminal connected to the switch included in the pre-regulator circuit 10 to be larger than the control terminal, the heat dissipation of the integrated circuit 80 can be effectively improved in a limited mounting area.

In addition, for example, in the tracker module 100 according to the present example, the integrated circuit 80 may include the PR switch portion 80a including the at least one switch included in the pre-regulator circuit 10. In the plan view of the module laminate 90, at least a part of the first power supply terminal may overlap at least a part of the PR switch portion 80a.

According to this, since at least a part of the first power supply terminal overlaps at least a part of the PR switch portion 80a, a heat transmission path from the switch included in the pre-regulator circuit 10 to the first power supply terminal is shortened. Thus, the heat dissipation of the integrated circuit 80 can be more effectively improved. Furthermore, a wire that connects the switch included in the pre-regulator circuit 10 to the first power supply terminal can be shortened, and a resistance loss of the pre-regulator circuit 10 can also be reduced.

In addition, for example, in the tracker module 100 according to the present example, the power supply terminal may include the second power supply terminal (for example, any of the terminals 211 to 218) that connects at least one capacitor (for example, at least one of the capacitors C10 to C16, C20, C30, and C40) included in the switched-capacitor circuit 20 to the at least one switch included in the switched-capacitor circuit 20. In the plan view of the module laminate 90, the second power supply terminal may be larger than the control terminal.

According to this, heat in the integrated circuit 80 can be effectively transmitted to the module laminate 90 through the second power supply terminal which is larger, and characteristic deterioration caused by heat can be suppressed. Particularly, in a case where the power supply voltage is supplied to a plurality of power amplifiers, a higher current flows in the switch included in the switched-capacitor circuit 20, and a larger amount of heat is generated. Accordingly, by forming the second power supply terminal connected to the switch included in the switched-capacitor circuit 20 to be larger than the control terminal, the heat dissipation of the integrated circuit 80 can be more effectively improved in a limited mounting area.

In addition, for example, in the tracker module 100 according to the present example, the at least one capacitor included in the switched-capacitor circuit 20 may include a flying capacitor (for example, any of the capacitors C11 to C16).

According to this, heat in the integrated circuit 80 can be effectively transmitted to the module laminate 90 through the second power supply terminal connected to the flying capacitor, and characteristic deterioration caused by heat can be suppressed. Particularly, a higher current than a current in a smoothing capacitor that smooths energy to be supplied to a load during switching between switches is input into and output from the flying capacitor that repeats charging and discharging to supply energy and charges to the load and the smoothing capacitor. Accordingly, by forming the second power supply terminal connecting the flying capacitor to the switch to be larger than the control terminal, the heat dissipation of the integrated circuit 80 can be more effectively improved in a limited mounting area.

In addition, for example, in the tracker module 100 according to the present example, a higher potential than a potential of another flying capacitor (for example, the capacitor C12, C13, C15, or C16) included in the switched-capacitor circuit 20 may be applied to the flying capacitor (for example, the capacitor C11 or C14).

According to this, heat in the integrated circuit 80 can be effectively transmitted to the module laminate 90 through the second power supply terminal connected to the flying capacitor to which a higher potential is applied, and characteristic deterioration caused by heat can be suppressed. Particularly, higher currents are input into and output from the flying capacitor to which a higher potential is applied. Accordingly, by forming the second power supply terminal connecting the flying capacitor to which a higher potential is applied to the switch to be larger than the control terminal, the heat dissipation of the integrated circuit 80 can be more effectively improved in a limited mounting area.

In addition, for example, in the tracker module 100 according to the present example, the integrated circuit 80 may include the SC switch portion 80b including the at least one switch included in the switched-capacitor circuit 20. In the plan view of the module laminate 90, at least a part of the second power supply terminal may overlap at least a part of the SC switch portion 80b.

According to this, since at least a part of the second power supply terminal overlaps at least a part of the SC switch portion 80b, a heat transmission path from the switch included in the switched-capacitor circuit 20 to the second power supply terminal is shortened. Thus, the heat dissipation of the integrated circuit 80 can be more effectively improved. Furthermore, a wire that connects the switch included in the switched-capacitor circuit 20 to the second power supply terminal can be shortened, and a resistance loss of the switched-capacitor circuit 20 can also be reduced.

In addition, for example, in the tracker module 100 according to the present example, the power supply terminal may include the third power supply terminal (for example, the terminal 130A or 130B) connected to the at least one switch included in the supply modulator 30A or 30B. In the plan view of the module laminate 90, the third power supply terminal may be larger than the control terminal.

According to this, heat in the integrated circuit 80 can be effectively transmitted to the module laminate 90 through the third power supply terminal which is larger, and characteristic deterioration caused by heat can be suppressed. Particularly, by forming the third power supply terminal connected to the switch included in the supply modulator 30A or 30B to be larger than the control terminal, heat of the supply modulator 30A or 30B can be more effectively transmitted to the module laminate 90 in a limited mounting area.

In addition, for example, in the tracker module 100 according to the present example, the integrated circuit 80 may include the OS switch portion 80c including the at least one switch included in the supply modulator 30A or 30B. In the plan view of the module laminate 90, at least a part of the third power supply terminal may overlap at least a part of the OS switch portion 80c.

According to this, since at least a part of the third power supply terminal overlaps at least a part of the OS switch portion 80c, a heat transmission path from the switch included in the supply modulator 30A or 30B to the third power supply terminal is shortened. Thus, the heat dissipation of the integrated circuit 80 can be more effectively improved. Furthermore, a wire that connects the switch included in the supply modulator 30A or 30B to the third power supply terminal can be shortened, and a resistance loss of the supply modulator 30A or 30B can also be reduced.

In addition, for example, in the tracker module 100 according to the present example, the power supply terminal may include the fourth power supply terminal (for example, any of the terminals 111 to 113) connected to the at least one switch included in the pre-regulator circuit 10 and the fifth power supply terminal (for example, any of the terminals 201 to 204) connected to the at least one switch included in the switched-capacitor circuit 20. The module laminate 90 may include the wire 941 that connects the fourth power supply terminal to the fifth power supply terminal. In the plan view of the module laminate 90, each of the fourth power supply terminal and the fifth power supply terminal may be larger than the control terminal.

According to this, heat in the integrated circuit 80 can be effectively transmitted to the module laminate 90 through the fourth power supply terminal and the fifth power supply terminal which are larger, and characteristic deterioration caused by heat can be suppressed. Particularly, in a case where the power supply voltage is supplied to a plurality of power amplifiers, a higher current flows in the switches included in the pre-regulator circuit 10 and the switched-capacitor circuit 20, and a larger amount of heat is generated. Accordingly, by forming the fourth power supply terminal and the fifth power supply terminal connected to the switches included in the pre-regulator circuit 10 and the switched-capacitor circuit 20 to be larger than the control terminal, the heat dissipation of the integrated circuit 80 can be more effectively improved in a limited mounting area. In addition, since the switch included in the pre-regulator circuit 10 is connected to the switch included in the switched-capacitor circuit 20 through the wire 941 outside the integrated circuit 80, the heat dissipation of the integrated circuit 80 can be improved, compared to that in a case where the switch included in the pre-regulator circuit 10 and the switch included in the switched-capacitor circuit 20 are connected through a wire in the integrated circuit 80.

In addition, for example, in the tracker module 100 according to the present example, the integrated circuit 80 may include the PR switch portion 80a including the at least one switch included in the pre-regulator circuit 10 and the SC switch portion 80b including the at least one switch included in the switched-capacitor circuit 20. In the plan view of the module laminate 90, at least a part of the fourth power supply terminal may overlap at least a part of the PR switch portion 80a, and at least a part of the fifth power supply terminal may overlap at least a part of the SC switch portion 80b.

According to this, since at least a part of the fourth power supply terminal overlaps at least a part of the PR switch portion 80a, a heat transmission path from the switch included in the pre-regulator circuit 10 to the fourth power supply terminal is shortened. Thus, the heat dissipation of the integrated circuit 80 can be more effectively improved. Furthermore, since at least a part of the fifth power supply terminal overlaps at least a part of the SC switch portion 80b, a heat transmission path from the switch included in the switched-capacitor circuit 20 to the fifth power supply terminal is shortened. Thus, the heat dissipation of the integrated circuit 80 can be more effectively improved.

In addition, for example, in the tracker module 100 according to the present example, the power supply terminal may include the sixth power supply terminal (for example, any of the terminals 201 to 204) connected to the at least one switch included in the switched-capacitor circuit 20 and the seventh power supply terminal (for example, any of the terminals 131A to 134A and 131B to 134B) connected to the at least one switch included in the supply modulator 30A or 30B. The module laminate 90 may include the wire 942 that connects the sixth power supply terminal to the seventh power supply terminal. In the plan view of the module laminate 90, each of the sixth power supply terminal and the seventh power supply terminal may be larger than the control terminal.

According to this, heat in the integrated circuit 80 can be effectively transmitted to the module laminate 90 through the sixth power supply terminal and the seventh power supply terminal which are larger, and characteristic deterioration caused by heat can be suppressed. In addition, since the switch included in the switched-capacitor circuit 20 is connected to the switch included in the supply modulator 30A or 30B through the wire 942 outside the integrated circuit 80, the heat dissipation of the integrated circuit 80 can be improved, compared to that in a case where the switch included in the switched-capacitor circuit 20 and the switch included in the supply modulator 30A or 30B are connected through a wire in the integrated circuit 80.

In addition, for example, in the tracker module 100 according to the present example, the integrated circuit 80 may include the SC switch portion 80b including the at least one switch included in the switched-capacitor circuit 20 and the OS switch portion 80c including the at least one switch included in the supply modulator 30A or 30B. In the plan view of the module laminate 90, at least a part of the sixth power supply terminal may overlap at least a part of the SC switch portion 80b, and at least a part of the seventh power supply terminal may overlap at least a part of the OS switch portion 80c.

According to this, since at least a part of the sixth power supply terminal overlaps at least a part of the SC switch portion 80b, a heat transmission path from the switch included in the switched-capacitor circuit 20 to the sixth power supply terminal is shortened. Thus, the heat dissipation of the integrated circuit 80 can be more effectively improved. Furthermore, since at least a part of the seventh power supply terminal overlaps at least a part of the OS switch portion 80c, a heat transmission path from the switch included in the supply modulator 30A or 30B to the seventh power supply terminal is shortened. Thus, the heat dissipation of the integrated circuit 80 can be more effectively improved.

In addition, for example, in the tracker module 100 according to the present example, in the plan view of the module laminate 90, the power supply terminal may be closer to the periphery of the integrated circuit 80 than the control terminal.

According to this, since the power supply terminal which is larger is disposed near the periphery of the integrated circuit 80, the integrated circuit 80 can be more strongly bonded to the module laminate 90 in the peripheral portion of the integrated circuit 80. Particularly, since a larger amount of thermal stress is generated in the peripheral portion of the integrated circuit 80 because of a difference between thermal expansion coefficients of the integrated circuit 80 and the module laminate 90, peeling between bonded portions of the integrated circuit 80 and the module laminate 90 can be more effectively suppressed.

In addition, for example, in the tracker module 100 according to the present example, in the plan view of the module laminate 90, the power supply terminal may have an elongated shape.

According to this, by forming the power supply terminal to have an elongated shape, a height of the power supply terminal and a height of the control terminal can be easily matched, compared to those in a case where the power supply terminal is formed to have a circular shape larger than the control terminal, and a manufacturing process can be simplified.

In addition, for example, in the tracker module 100 according to the present example, the power supply terminal may be a bump electrode made of copper.

According to this, the power supply terminal can be more easily formed using electrolytic or electroless plating, and thermal resistance of the power supply terminal can be reduced, compared to that of other metal materials. Accordingly, it is possible to simplify a manufacturing process and further improve the heat dissipation.

In addition, according to a different point of view, the tracker module 100 according to the present example includes the module laminate 90 and the integrated circuit 80 disposed on the module laminate 90. The integrated circuit 80 includes at least one switch included in the pre-regulator circuit 10, at least one switch included in the switched-capacitor circuit 20, at least one switch included in the supply modulator 30A, a power supply terminal connected to at least one of the at least one switch included in the pre-regulator circuit 10, the at least one switch included in the switched-capacitor circuit 20, and the at least one switch included in the supply modulator 30A, and a control terminal connected to the RFIC 5. In the plan view of the module laminate 90, the power supply terminal is larger than the control terminal. The switched-capacitor circuit 20 includes the capacitor C12 including the first electrode and the second electrode, and the capacitor C15 including the third electrode and the fourth electrode. The at least one switch included in the switched-capacitor circuit 20 includes the switches S21 to S24 and S31 to S34. One end of the switch S21 and one end of the switch S22 are connected to the first electrode of the capacitor C12. One end of the switch S32 and one end of the switch S31 are connected to the second electrode of the capacitor C12. One end of the switch S23 and one end of the switch S24 are connected to the third electrode of the capacitor C15. One end of the switch S34 and one end of the switch S33 are connected to the fourth electrode of the capacitor C15. The other end of the switch S21, the other end of the switch S32, the other end of the switch S23, and the other end of the switch S34 are connected to each other. The other end of the switch S22 is connected to the other end of the switch S24, and the other end of the switch S31 is connected to the other end of the switch S33. The supply modulator 30A includes the terminal 130A. The at least one switch included in the supply modulator 30A includes the switch S53A connected between the terminal 130A and the other end of the switch S21, the other end of the switch S32, the other end of the switch S23, and the other end of the switch S34, and the switch S52A connected between the terminal 130A and the other end of the switch S22 and the other end of the switch S24. The pre-regulator circuit 10 includes the input terminal 110. The at least one switch included in the pre-regulator circuit 10 includes the switch S71 connected between the input terminal 110 and one end of the power inductor L71, and the switch S72 connected between the one end of the power inductor L71 and the ground. The other end of the power inductor L71 is connected to the other end of the switch S21, the other end of the switch S32, the other end of the switch S23, and the other end of the switch S34.

According to this, heat in the integrated circuit 80 can be effectively transmitted to the module laminate 90 through the power supply terminal which is larger, and characteristic deterioration caused by heat can be suppressed. Particularly, in the switches included in the pre-regulator circuit 10, the switched-capacitor circuit 20, or the supply modulator 30A, since a higher current than a current in the digital control circuit 60 flows, a larger amount of heat is generated. By forming the power supply terminal connected to a heat source to be larger than the control terminal, heat dissipation of the integrated circuit 80 can be effectively improved in a limited mounting area.

In addition, according to a different point of view, the tracker module 100 according to the present example includes the module laminate 90 and the integrated circuit 80 disposed on the module laminate 90. The integrated circuit 80 includes at least one switch included in the pre-regulator circuit 10 that is configured to convert the input voltage into the first voltage, at least one switch included in the switched-capacitor circuit 20 that is configured to generate the plurality of second voltages having the plurality of respective discrete voltage levels from the first voltage, at least one switch included in the supply modulator 30A or 30B that is configured to select at least one of the plurality of second voltages based on the envelope signal, and a power supply terminal connected to at least one of the at least one switch included in the pre-regulator circuit 10, the at least one switch included in the switched-capacitor circuit 20, and the at least one switch included in the supply modulator 30A or 30B. In the plan view of the module laminate 90, the power supply terminal has an elongated shape.

According to this, heat in the integrated circuit 80 can be effectively transmitted to the module laminate 90 through the power supply terminal having an elongated shape, and characteristic deterioration caused by heat can be suppressed. Particularly, in the switches included in the pre-regulator circuit 10, the switched-capacitor circuit 20, or the supply modulator 30A or 30B, since a higher current flows, a larger amount of heat is generated. By forming a shape of the power supply terminal connected to a heat source to be an elongated shape, the heat dissipation of the integrated circuit 80 can be effectively improved in a limited mounting area.

While all of the power supply terminals are larger than the control terminal in the plan view of the module laminate 90 in the present example, the present disclosure is not limited thereto. That is, at least one of the power supply terminals may be larger than the control terminal in the plan view of the module laminate 90. Similarly, all of the power supply terminals do not necessarily have an elongated shape in the plan view of the module laminate 90. That is, at least one of the power supply terminals may have an elongated shape in the plan view of the module laminate 90.

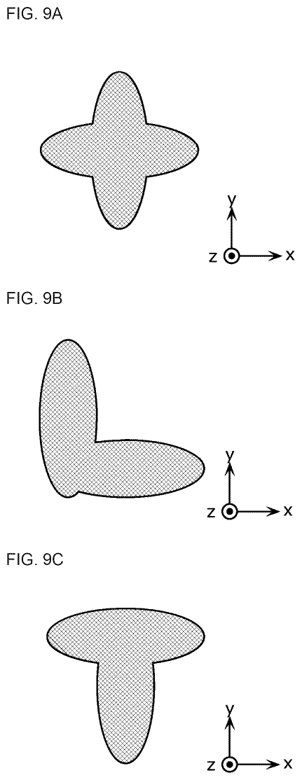

In addition, the shape of the power supply terminal in the plan view of the module laminate 90 is not limited to the elongated shape. For example, as illustrated in FIG. 9A, the power supply terminal may have a cross shape in the plan view of the module laminate 90. In addition, for example, as illustrated in FIG. 9B, the power supply terminal may have an L-shape in the plan view of the module laminate 90. In addition, for example, as illustrated in FIG. 9C, the power supply terminal may have a T-shape in the plan view of the module laminate 90.

In addition, shapes and/or sizes may vary among the power supply terminals. For example, in the plan view of the module laminate 90, at least one of the power supply terminals may be larger than another at least one of the power supply terminals. In addition, for example, in the plan view of the module laminate 90, at least one of the power supply terminals may have an elongated shape, and another at least one of the power supply terminals may have a circular shape.

### Additional Exemplary Embodiments

While the tracker module according to the present disclosure has been described above based on the exemplary embodiment and the example, the tracker module according to the present disclosure is not limited to the exemplary embodiment and the example. The present disclosure also includes other embodiments and other examples implemented by combining any constituents in the embodiment and the example, modification examples obtained by carrying out various modifications perceived by those skilled in the art to the embodiment and the example without departing from the gist of the present disclosure, and various devices incorporating the tracker module.

For example, in the circuit configurations of various circuits according to the exemplary embodiment, other circuit elements, wires, and the like may be provided on the paths connecting each circuit element and the signal paths disclosed in the drawings. For example, an impedance matching circuit may be provided between the power amplifier 2A and the filter 3A and/or between the filter 3A and the antenna 6.

In addition, for example, in the tracker module 100 according to the example, the capacitor C51A and/or C52A may be included in the integrated circuit 80. Similarly, the capacitor C51B and/or C52B may be included in the integrated circuit 80. This can contribute to size reduction of the tracker module 100.

### INDUSTRIAL APPLICABILITY

The present disclosure can be widely used for communication devices such as a mobile phone as a tracker module that supplies a power supply voltage to a power amplifier.

### REFERENCE SIGNS LIST

1 Power supply circuit
2A, 2B Power amplifier
3A, 3B Filter
4 PA control circuit
5 RFIC
6 Antenna
7 Communication device
10 Pre-regulator circuit
20 Switched-capacitor circuit
30A, 30B Supply modulator
40A, 40B Filter circuit
50 Direct current power source
60 Digital control circuit
61 First controller
62 Second controller
80 Integrated circuit
80a PR switch portion
80b SC switch portion
80c OS switch portion
80d Digital control portion
90 Module laminate
90a, 90b Main surface
91 Resin member
93 Shield electrode layer
100 Tracker module
110, 140A, 140B Input terminal
111, 112, 113, 114, 115, 116, 130A, 130B, 131A, 131B, 132A, 132B, 133A, 133B,
134A, 134B, 201, 202, 203, 204, 211, 212, 213, 214, 215, 216, 217, 218, 601, 602, 603, 604, 605, 606 Terminal
141A, 141B Output terminal
150 Land electrode
941, 942 Wire
C10, C11, C12, C13, C14, C15, C16, C20, C30, C40, C51A, C51B, C52A, C52B, C61, C62, C63, C64, C81, C82 Capacitor
L51A, L51B, L52A, L52B, L53A, L53B Inductor
L71 Power inductor
R51A, R51B Resistor
S1, S2, S3A, S3B Control signal
S11, S12, S13, S14, S21, S22, S23, S24, S31, S32, S33, S34, S41, S42, S43, S44, S51A, S51B, S52A, S52B, S53A, S53B, S54A, S54B, S61, S62, S63, S71, S72 Switch
V1, V2, V3, V4 Voltage

What is claimed:

1. A tracker module comprising:
a module laminate configured to provide interconnections to circuit components on the module laminate; and
at least one integrated circuit disposed on the module laminate, the at least one integrated circuit including:
one or more first switches included in a pre-regulator circuit, the pre-regulator circuit being configured to convert an input voltage into a first voltage;
one or more second switches included in a switched-capacitor circuit, the switched-capacitor circuit being configured to generate a plurality of second voltages having a plurality of respective discrete voltage levels from the first voltage;
one or more third switches included in a supply modulator, the supply modulator being configured to select at least one of the plurality of second voltages based on a digital control logic signal that is generated based on an envelope signal;
at least a power supply terminal connected to at least one of the one or more first switches, the one or more second switches and the one or more third switches; and
a control terminal that receives the digital control logic signal;
wherein, in a plan view of the module laminate, the power supply terminal has a larger size than the control terminal.

2. The tracker module according to claim 1, wherein:
at least the power supply terminal includes a first power supply terminal that connects at least one of a power inductor and a capacitor included in the pre-regulator circuit to at least a first switch in the one or more first switches in the pre-regulator circuit; and
in the plan view of the module laminate, the first power supply terminal has a larger size than the control terminal.

3. The tracker module according to claim 2, wherein:
the at least one integrated circuit includes a first area for a first switch portion including the one or more first switches; and
in the plan view of the module laminate, at least a part of the first power supply terminal overlaps at least a part of the first area for the first switch portion.

4. The tracker module according to claim 3, wherein:
at least the power supply terminal includes a second power supply terminal that connects at least a first capacitor included in the switched-capacitor circuit to a second switch in the one or more second switches; and
in the plan view of the module laminate, the second power supply terminal has a larger size than the control terminal.

5. The tracker module according to claim 4, wherein the first capacitor included in the switched-capacitor circuit includes a flying capacitor.

6. The tracker module according to claim 5, wherein the first capacitor is configured to be applied with a higher potential than a second flying capacitor included in the switched-capacitor circuit.

7. The tracker module according to claim 4, wherein:
the at least one integrated circuit includes a second area for a second switch portion including the one or more second switches; and
in the plan view of the module laminate, at least a part of the second power supply terminal overlaps at least a part of second area for the second switch portion.

8. The tracker module according to claim 1, wherein:
at least the power supply terminal includes a third power supply terminal connected to a third switch in the one or more third switches; and
in the plan view of the module laminate, the third power supply terminal has a larger size than the control terminal.

9. The tracker module according to claim 8, wherein:
the at least one integrated circuit includes a third area for a third switch portion including the one or more third switches; and
in the plan view of the module laminate, at least a part of the third power supply terminal overlaps at least a part of the third area for the third switch portion.

10. The tracker module according to claim 1, wherein at least the power supply terminal includes:
a fourth power supply terminal connected to a first switch in the one or more first switches; and
a fifth power supply terminal connected to a second switch in the one or more second switches;
wherein the module laminate includes a first wire that connects the fourth power supply terminal to the fifth power supply terminal; and
wherein, in the plan view of the module laminate, each of the fourth power supply terminal and the fifth power supply terminal has a larger size than the control terminal.

11. The tracker module according to claim 10, wherein the at least one integrated circuit includes:
a first area for a first switch portion including the one or more first switches; and
a second area for a second switch portion including the one or more second switches; and
wherein, in the plan view of the module laminate, at least a part of the fourth power supply terminal overlaps at least a part of the first area, and at least a part of the fifth power supply terminal overlaps at least a part of the second area.

12. The tracker module according to claim 1, wherein the power supply terminal includes:
a sixth power supply terminal connected to a second switch in the one or more second switches; and
a seventh power supply terminal connected to a third switch in the one or more third switches;
wherein the module laminate includes a second wire that connects the sixth power supply terminal to the seventh power supply terminal; and
wherein, in the plan view of the module laminate, each of the sixth power supply terminal and the seventh power supply terminal has a larger size than the control terminal.

13. The tracker module according to claim 12, wherein the at least one integrated circuit includes:
a second area for a second switch portion including the one or more second switches; and
a third area for a third switch portion including the one or more third switches; and
wherein in the plan view of the module laminate, at least a part of the sixth power supply terminal overlaps at least a part of the second area; and at least a part of the seventh power supply terminal overlaps at least a part of the third area.

14. The tracker module according to claim 1, wherein:
the at least one integrated circuit includes a single integrated circuit with the power supply terminal and the control terminal; and
in the plan view of the module laminate, the power supply terminal is closer to a periphery of the single integrated circuit than the control terminal.

15. The tracker module according to claim 1, wherein, in the plan view of the module laminate, the power supply terminal has an elongated shape.

16. The tracker module according to claim 1, wherein the power supply terminal is a bump electrode made of copper.

17. A tracker module, comprising:
a module laminate; and
at least one integrated circuit disposed on the module laminate and that includes:
one or more first switches included in a pre-regulator circuit;
one or more second switches included in a switched-capacitor circuit;
one or more third switches included in a supply modulator;
a power supply terminal connected to at least one of the one or more first switches, the one or more second switches, and the one or more third switches; and
a control terminal that receives a digital control logic signal,
wherein, in a plan view of the module laminate, the power supply terminal has a larger size than the control terminal;
wherein the switched-capacitor circuit includes:
a first capacitor including a first electrode and a second electrode; and
a second capacitor including a third electrode and a fourth electrode;
wherein the one or more second switches in the switched-capacitor circuit includes a first capacitor switch, a second capacitor switch, a third capacitor switch, a fourth capacitor switch, a fifth capacitor switch, a sixth capacitor switch, a seventh capacitor switch, and an eighth capacitor switch;
wherein:
a first end of the first capacitor switch and a first end of the third capacitor switch are connected to the first electrode;
a first end of the second capacitor switch and a first end of the fourth capacitor switch are connected to the second electrode;
a first end of the fifth capacitor switch and a first end of the seventh capacitor switch are connected to the third electrode;
a first end of the sixth capacitor switch and a first end of the eighth capacitor switch are connected to the fourth electrode;
a second end of the first capacitor switch, a second end of the second capacitor switch, a second end of the fifth capacitor switch, and a second end of the sixth capacitor switch are connected to each other;
a second end of the third capacitor switch is connected to a second end of the seventh capacitor switch;
a second end of the fourth capacitor switch is connected to a second end of the eighth capacitor switch;
wherein the supply modulator includes an output terminal;
wherein the one or more third switches included in the supply modulator includes:
a first modulate switch connected between the output terminal and the second end of the first capacitor switch, the second end of the second capacitor switch, the second end of the fifth capacitor switch, and the second end of the sixth capacitor switch; and
a second modulate switch connected between the output terminal and the second end of the third capacitor switch and the second end of the seventh capacitor switch;
wherein the pre-regulator circuit includes an input terminal;
wherein the one or more first switches in the pre-regulator circuit includes:
a first pre-regulator switch connected between the input terminal and a first end of a power inductor; and
a second pre-regulator switch connected between the first end of the power inductor and a ground; and
wherein a second end of the power inductor is connected to the second end of the first capacitor switch, the second end of the second capacitor switch, the second end of the fifth capacitor switch, and the second end of the sixth capacitor switch.

18. A tracker module comprising:
a module laminate; and
at least one integrated circuit disposed on the module laminate, and that includes:
one or more first switches included in a pre-regulator circuit, the pre-regulator circuit being configured to convert an input voltage into a first voltage;
one or more second switches included in a switched-capacitor circuit, the switched-capacitor circuit being configured to generate, from the first voltage, a plurality of second voltages having a plurality of respective discrete voltage levels;
one or more third switches included in a supply modulator, the supply modulator being configured to select at least one of the plurality of second voltages based on an envelope signal; and
a power supply terminal connected to at least one of the one or more first switches in the pre-regulator circuit, the one or more second switches in the switched-capacitor circuit, and the one or more third switches in the supply modulator; and
wherein, in a plan view of the module laminate, the power supply terminal has an elongated shape.

19. The tracker module according to claim 18, wherein the power supply terminal is connected to one of the one or more first switches in the pre-regulator circuit, and in the plan view of the module laminate, at least a part of the power supply terminal overlaps with an area of the at least one integrated circuit for the one or more first switches.

20. The tracker module according to claim 18, wherein the power supply terminal is connected to one of the one or more second switches in the switched-capacitor circuit, and in the plan view of the module laminate, at least a part of the power supply terminal overlaps with an area of the at least one integrated circuit for the one or more second switches.
